(19) United States
(12) Patent Application Publication
(10) Pub. No.: US 2026/0188151 A1
(43) Pub. Date: Jul. 2, 2026

(54) Display Panel, Display Apparatus and Crack Detection Method

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yuqun LU, Beijing (CN); Zeliang LI, Beijing (CN); Jiandong BAO, Beijing (CN); Wei WANG, Beijing (CN); Shaojie QIN, Beijing (CN); Hua TAN, Beijing (CN); Zijin YE, Beijing (CN)

(21) Appl. No.: 18/727,704

(22) PCT Filed: May 8, 2023
(86) PCT No.: PCT/CN2023/092832

§ 371 Date: Jul. 10, 2024

(51) Int. Cl. G09G 3/00; G09G 3/3233; H10K 59/121; H10K 59/131; H10K 59/95

(52) U.S. Cl. CPC G09G 3/006; G09G 3/3233; H10K 59/1213; H10K 59/131; H10K 59/95; G09G 2300/0426; G09G 2300/0819; G09G 2300/0842; G09G 2300/0861

(57) ABSTRACT

A display panel includes a base substrate (10), a plurality of sub-pixels (PX), a plurality of data lines (DL), first detection lines (31a, 31b), and first detection control units (33a, 33b). The first detection control units (33a, 33b) are electrically connected to the first detection lines (31a, 31b) and are configured to provide a first test signal to the first detection lines (31a, 31b). The first detection lines (31a, 31b) are electrically connected to a plurality of sub-pixels (PX) of the display region (AA) in any of the following ways: the first detection lines (31a, 31b) are electrically connected to anodes of light emitting elements (62) of the plurality of sub-pixels of the display region (AA); the first detection lines (31a, 31b) are electrically connected to source electrodes of data write transistors of pixel circuits (61) of a plurality of sub-pixels of the display region (AA).

### CROSS-REFERENCE TO RELATED APPLICATION

The present application is a U.S. National Phase Entry of International Application No. PCT/CN2023/092832 having an international filing date of May 8, 2023. The above-identified application is hereby incorporated by reference.

### TECHNICAL FIELD

The present disclosure relates to, the field of display technologies, in particular to a display panel, a display apparatus, and a method for detecting a crack.

### BACKGROUND

Usually, a detection module or circuit is set on the periphery of the display panel to detect whether there are crack defects in the periphery (edge region) of the display panel during production and transportation. At present, the following two detection methods are usually used: eddy current testing (ET testing) and resistance detection. The eddy current testing is conducted by using the Panel Crack Detection (PCD) circuit to detect bright lines on the display screen to determine if there are cracks in the periphery of the panel; and the resistance detection is to detect the resistance between PCD lines, and determine whether there are cracks based on whether there is an abnormal resistance value. However, the above-mentioned detection methods can only detect whether there are cracks in the edge region, and can not accurately locate the location of defects. For example, for a large-size display panel, workers need to use a microscope to slowly find the crack position in the whole edge region of the display panel, which will consume a lot of time and energy of workers and lead to extremely low work efficiency.

### SUMMARY

The following is a summary of subject matters described herein in detail. This summary is not intended to limit the protection scope of claims.

Embodiments of the present disclosure provide a display panel, a display apparatus and a method for detecting a crack.

In one aspect, the present embodiment provides a display panel including a base substrate, a plurality of sub-pixels and a plurality of data lines, at least one first detection line, and at least one first detection control unit. The base substrate includes a display region and a peripheral region located at a periphery of the display region. The plurality of sub-pixels and the plurality of data lines are located in the display region, the plurality of sub-pixels are electrically connected with the plurality of data lines, and at least one sub-pixel of the plurality of sub-pixels includes a pixel circuit and a light emitting element. The pixel circuit is electrically connected with the light emitting element and is configured to drive the light emitting element to emit light. At least one first detection line and at least one first detection control unit are located at the peripheral region, the at least one first detection control unit is electrically connected with the at least one first detection line and is configured to provide a first test signal to the at least one first detection line. At least one first detection line is electrically connected with the plurality of sub-pixels of the display region in any of the following ways; at least one first detection line is electrically connected with anodes of light emitting elements of the plurality of sub-pixels of the display region; at least one first detection line is electrically connected to source electrodes of data write transistors of pixel circuits of the plurality of sub-pixels of the display region; at least one first detection line is electrically connected with a plurality of data lines of the display region, wherein at least one of the plurality of data lines is electrically connected with a plurality of sub-pixels arranged along the first direction, and at least one first detection line is at least located within peripheral regions on opposite sides of the display region along the first direction.

In some exemplary implementations, the at least one first detection line includes a first main line and a plurality of first sub-lines electrically connected to the first main line, and each first sub-line is electrically connected to at least one sub-pixel of the display region; and the plurality of first sub-lines are arranged sequentially along an extension direction of the first main line.

In some exemplary implementations, the peripheral region is further provided with a gate drive circuit. The first main line is located on a side of the gate drive circuit close to the display region, and a portion of the line segment of each first sub-line is located on a side of the gate drive circuit away from the display region.

In some exemplary implementations, the peripheral region is further provided with a gate drive circuit. The first main line is located on a side of the gate drive circuit away from the display region, and the plurality of first sub-lines are located on a side of the first main line close to the display region.

In some exemplary implementations, the plurality of sub-pixels electrically connected to the plurality of first sub-lines of the first detection line include a plurality of sub-pixels within the display region closest to the first main line and arranged along the extension direction of the first main line.

In some exemplary implementations, each first sub-line at least includes a first line segment, a second line segment, and a first cross-line; wherein both ends of the first cross-line are electrically connected to the first line segment and the second line segment, respectively, the first line segment is located on a side of the gate drive circuit away from the display region, and the second line segment is located on a side of the gate drive circuit close to the display region; an orthographic projection of the first cross-line on the base substrate is at least partially overlapped with an orthographic projection of the gate drive circuit on the base substrate; and the first cross-line line is located on a side of the first line segment and the second line segment close to the base substrate.

In some exemplary implementations, in a direction perpendicular to the display panel, the display panel at least includes a base substrate and a bottom shielding metal layer, and a semiconductor layer, a first gate metal layer, a second gate metal layer, a first source-drain metal layer and a second source-drain metal layer which are arranged on the base substrate. The first cross-line is located in the bottom shielding metal layer, and the first line segment and the second line segment are located in the first gate metal layer.

In some exemplary implementations, the at least one first detection control unit includes a first detection transistor, wherein a gate electrode of the first detection transistor is electrically connected with the first detection control line, a first electrode of the first detection transistor is electrically connected with a first test signal transmission line, and a second electrode of the first detection transistor is electrically connected with the first detection line.

In some exemplary implementations, the display panel further includes a second detection line and at least one second detection control unit which are located at the peripheral region; the at least one second detection control unit is electrically connected to the second detection line, and is configured to provide a second test signal to the second detection line. The second detection line is electrically connected with the plurality of sub-pixels of the display region. A connection mode between the second detection line and the plurality of sub-pixels of the display region is different from a connection mode between the first detection line and the plurality of sub-pixels of the display region.

In some exemplary implementations, the second detection line includes a second main line and a plurality of second sub-lines electrically connected to the second main line; each second sub-line is electrically connected with at least one sub-pixel of the display region, and the plurality of second sub-lines are sequentially arranged along an extension direction of the second main line. The extension direction of the second main line intersects with the extension direction of the first main line of the first detection line.

In some exemplary implementations, the plurality of first sub-lines of the at least one first detection line are electrically connected with the anodes of the light emitting elements of the plurality of sub-pixels of the display region in one-to-one correspondence. The plurality of second sub-lines of the second detection line are electrically connected with the source electrodes of the data write transistors of the pixel circuits of the plurality of sub-pixels of the display region in one-to-one correspondence.

In some exemplary implementations, the plurality of first sub-lines of the at least one first detection line are electrically connected to the plurality of data lines of the display region in one-to-one correspondence; and the plurality of data lines extend along the first direction. The plurality of second sub-lines of the second detection line are electrically connected with a plurality of first power supply lines of the display region in one-to-one correspondence, the plurality of first power supply lines extend along a second direction, and the second direction intersects with the first direction.

In some exemplary implementations, the peripheral region is further provided with a first power supply bezel line. The second main line is located on a side of the first power supply bezel line close to the display region, and a portion of each second sub-line is located on a side of the first power supply bezel line away from the display region.

In some exemplary implementations, the peripheral region is further provided with a first power supply bezel line. The second main line is located on a side of the first power supply bezel line away from the display region, and the plurality of second sub-lines are located on a side of the second main line close to the display region.

In some exemplary implementations, the plurality of sub-pixels electrically connected to the plurality of second sub-lines of the second detection line include a plurality of sub-pixels within the display region closest to the second main line and arranged along the extension direction of the second main line.

In some exemplary implementations, each second sub-line at least includes a third line segment, a fourth line segment, and a third cross-line; wherein both ends of the third cross-line are electrically connected to the third line segment and the fourth line segment, respectively, the third line segment is located on a side of the first power supply bezel line away from the display region, and the fourth line segment is located on a side of the first power supply bezel line close to the display region; an orthographic projection of the third cross-line on the base substrate is at least partially overlapped with an orthographic projection of the first power supply bezel line on the base substrate; and the third cross-line line is located on a side of the third line segment and the fourth line segment close to the base substrate.

In some exemplary implementations, in a direction perpendicular to the display panel, the display panel at least includes a base substrate and a bottom shielding metal layer, and a semiconductor layer, a first gate metal layer, a second gate metal layer, a first source-drain metal layer and a second source-drain metal layer which are arranged on the base substrate. The third cross-line is located on the bottom shielding metal layer, and the third line segment and the fourth line segment are located in the first gate metal layer.

In some exemplary implementations, the second detection control unit includes a second detection transistor, wherein a gate electrode of the second detection transistor is electrically connected with the second detection control line, a first electrode of the second detection transistor is electrically connected with a second test signal transmission line, and a second electrode of the second detection transistor is electrically connected with the second detection line.

In another aspect, an embodiment provides a display apparatus, including the aforementioned display panel.

On the other hand, the present embodiment provides a crack detection method, which is applied to the display panel as described above, including: providing a first test signal to a first detection line through a first detection control unit, and determining whether there is a crack in a peripheral region and a position where the crack is located according to a light emitting state of a plurality of sub-pixels electrically connected to the first detection line.

In some exemplary implementations, the crack detection method further includes: providing a second test signal to a second detection line through a second detection control unit, and determining whether there is a crack in the peripheral region and a position where the crack is located according to a light emitting state of a plurality of sub-pixels electrically connected to the second detection line.

On the other hand, the present embodiment provides a display panel, including a base substrate, a plurality of sub-pixels, at least one first detection line, and at least one first detection control unit. The base substrate includes a display region and a peripheral region located at a periphery of the display region. The plurality of sub-pixels are located in the display region. At least one first detection line and at least one first detection control unit are located at the peripheral region, the at least one first detection control unit is electrically connected with the at least one first detection line and is configured to provide a first test signal to the at least one first detection line. The at least one first detection line is electrically connected with the plurality of sub-pixels of the display region. The at least one first detection line includes a first main line, and a plurality of first sub-lines electrically connected with the first main line, the plurality of first sub-lines extend to the display region, and each first sub-line is electrically connected with at least one sub-pixel of the display region. A portion of a line segment of at least one first sub-line of the plurality of first sub-lines is located on a side of the first main line away from the display region.

In some exemplary implementations, the peripheral region is further provided with a gate drive circuit. The first main line is located on a side of the gate drive circuit close to the display region, and a portion of a line segment of each first sub-line is located on a side of the gate drive circuit away from the display region.

In some exemplary implementations, the display panel further includes a second detection line and at least one second detection control unit which are located at the peripheral region; and the at least one second detection control unit is electrically connected to the second detection line, and is configured to provide a second test signal to the second detection line. The second detection line is electrically connected with the plurality of sub-pixels of the display region. A connection mode between the second detection line and the plurality of sub-pixels of the display region is different from a connection mode between the first detection line and the plurality of sub-pixels of the display region.

In some exemplary implementations, the second detection line includes a second main line and a plurality of second sub-lines electrically connected to the second main line; each second sub-line is electrically connected with at least one sub-pixel of the display region, and the plurality of second sub-lines are sequentially arranged along an extension direction of the second main line. The extension direction of the second main line intersects with the extension direction of the first main line of the first detection line.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a planar schematic diagram of a display panel according to at least one embodiment of the present disclosure.

FIG. 2 is an equivalent circuit diagram of a pixel circuit according to at least one embodiment of the present disclosure.

FIG. 3 is a schematic diagram of a display panel according to at least one embodiment of the present disclosure.

FIG. 4 is a schematic diagram of a partial wiring of a display panel according to at least one embodiment of the present disclosure.

FIG. 5 is a schematic partial sectional view of the first sub-line shown in FIG. 4.

FIG. 6 is a schematic partial sectional view of a display region according to at least one embodiment of the present disclosure.

FIG. 7 is a schematic diagram of another partial wiring of a display substrate according to at least one embodiment of the present disclosure.

FIG. 8 is a schematic partial sectional view of the second sub-line shown in FIG. 7.

FIG. 9 is a schematic diagram of a connection between a second sub-line and a pixel circuit according to at least one embodiment of the present disclosure.

FIG. 10A is a schematic diagram of a pixel circuit after a semiconductor layer is formed in FIG. 9.

FIG. 10B is a schematic diagram of a pixel circuit after a first gate metal layer is formed in FIG. 9.

FIG. 10C is a schematic diagram of a pixel circuit after a second gate metal layer is formed in FIG. 9.

FIG. 10D is a schematic diagram of a pixel circuit after a source-drain metal layer is formed in FIG. 9.

FIG. 11A and FIG. 11B are schematic diagrams of display patterns for crack detection of a third bezel region and a fourth bezel region according to at least one embodiment of the present disclosure.

FIG. 12 is a schematic diagram of a display pattern for crack detection of a second bezel region according to at least one embodiment of the present disclosure.

FIG. 13 is a schematic diagram of another display panel according to at least one embodiment of the present disclosure.

FIG. 14 is a schematic diagram of another display panel according to at least one embodiment of the present disclosure.

FIG. 15 is a schematic diagram of another display panel according to at least one embodiment of the present disclosure.

FIG. 16 is a schematic diagram of another display panel according to at least one embodiment of the present disclosure.

FIG. 17 is a planar schematic diagram of another display panel according to at least one embodiment of the present disclosure.

FIG. 18 is a schematic diagram of another display panel according to at least one embodiment of the present disclosure.

FIG. 19 is a schematic diagram of another display panel according to at least one embodiment of the present disclosure.

FIG. 20 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends in in the B direction” in the present disclosure means “the main portion of A extends in the B direction”.

The present embodiment provides a display panel including a base substrate, a plurality of sub-pixels and a plurality of data lines, at least one first detection line, and at least one first detection control unit. The base substrate includes a display region and a peripheral region located at a periphery of the display region. The plurality of sub-pixels and the plurality of data lines are located in the display region, the plurality of sub-pixels are electrically connected with the plurality of data lines, and at least one sub-pixel of the plurality of sub-pixels includes a pixel circuit and a light emitting element. The pixel circuit is electrically connected with the light emitting element and is configured to drive the light emitting element to emit light. At least one first detection line and at least one first detection control unit are located at the peripheral region, the at least one first detection control unit is electrically connected with the at least one first detection line and is configured to provide a first test signal to the at least one first detection line. At least one first detection line is electrically connected with the plurality of sub-pixels of the display region in any of the following ways; at least one first detection line is electrically connected with anodes of light emitting elements of the plurality of sub-pixels of the display region; at least one first detection line is electrically connected to source electrodes of data write transistors of pixel circuits of the plurality of sub-pixels of the display region; at least one first detection line is electrically connected with a plurality of data lines of the display region, wherein at least one of the plurality of data lines is electrically connected with a plurality of sub-pixels arranged along the first direction, and at least one first detection line is at least located within peripheral regions on opposite two sides of the display region along the first direction.

In some examples, the first detection line may be electrically connected to the anodes of the light emitting elements of the plurality of sub-pixels of the display region. In the crack detection process, when an anode of a light emitting element receives the first test signal transmitted by the first detection line, the light emitting element may be lit; on the contrary, when there is a crack at a position where the first detection line is located, the first detection line cannot transmit the first test signal to the anode of the corresponding light emitting element, and the corresponding light emitting element does not emit light. In this way, a position of an edge crack may be positioned according to a position of a dark line in the display region.

In some examples, the first detection line may be electrically connected to source electrodes of data write transistors of pixel circuits of a plurality of sub-pixels of the display region. In the crack detection process, when a source electrode of a data write transistor of a pixel circuit receives the first test signal transmitted by the first detection line, the light emitting element driven by the pixel circuit does not emit light; and on the contrary, when there is a crack at a position where the first detection line is located, the first detection line cannot transmit the first test signal to the corresponding pixel circuit, and the light emitting element driven by the pixel circuit may emit light. In this way, a position of an edge crack may be located according to a position of a light line in the display region.

In some examples, the first detection line may be electrically connected to a plurality of data lines within the display region, and the plurality of data lines may extend along the first direction (e.g. lateral wiring). In the crack detection process, when the data line receives the first test signal transmitted by the first detection line, the pixel circuit connected to the data line may drive the light emitting element not to emit light; on the contrary, when there is a crack at a position where the first detection line is located, the first detection line cannot transmit the first test signal to the corresponding data line, and the pixel circuit connected to the data line may drive the light emitting element to emit light. In this way, a position of an edge crack may be located according to a position of a light line in the display region.

In the display panel according to an embodiment, the first detection control unit is used to provide a first test signal to the first detection line, and the first detection line is electrically connected with a plurality of sub-pixels of the display region. According to a voltage control of the first test signal and display results of the plurality of sub-pixels of the display region, it is convenient to determine whether there is a crack in the peripheral region and accurately locate the position where there is an edge crack in the peripheral region, thereby improving the working efficiency.

Solutions of the embodiments will be described below through some examples.

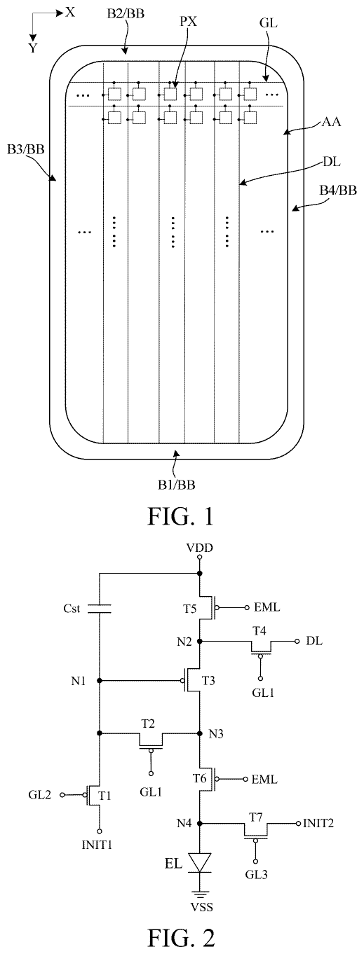

FIG. 1 is a planar schematic diagram of a display panel according to at least one embodiment of the present disclosure. In some examples, as shown in FIG. 1, the display panel according to the present embodiment may include a display region AA, and a peripheral region BB surrounding the display region AA. The peripheral region BB may include a third bezel region B3 and a fourth bezel region B4 which are located on opposite sides of the display region AA along a first direction X, and a first bezel region B1 and a second bezel region B2 which are located on opposite sides of the display region AA along a second direction Y. Herein, the first bezel region B1 may also be referred to as a lower bezel, the second bezel region B2 may also be referred to as an upper bezel, the third bezel region B3 may also be referred to as a left bezel, and the fourth bezel region B4 may also be referred to as a right bezel. The first bezel region B1 is in communication with the third bezel region B3 and the fourth bezel region B4, and the second bezel region B2 is in communication with the third bezel region B3 and the fourth bezel region B4.

In some examples, as shown in FIG. 1, the display region AA may be in a shape of a rectangle, e.g., a rounded rectangle. However, the present embodiment is not limited thereto. For example, the display region may be in another shape, such as a circle, an oval and the like.

In some examples, as shown in FIG. 1, the third bezel region B3 and the fourth bezel region B4 may include a circuit region, a power supply line region, a crack dam region, and a cutting region arranged sequentially along a direction of the display region AA. The circuit region may be connected to the display region AA, and the circuit region may include a gate drive circuit, for example, the gate drive circuit may include a plurality of cascaded shift registers, and the plurality of shift registers may be electrically connected to a plurality of gate lines GL in the display region AA. The power supply line region is connected to the circuit region and may at least include a low-level power supply line. The low-level power supply line may extend along a direction parallel to an edge of the display region and is connected to a cathode in the display region AA. The crack dam region may be connected to the power supply line region and may at least include a plurality of cracks disposed on the composite insulation layer. The cutting region may be connected to the crack dam region and may at least include a cutting groove arranged on the composite insulation layer, and the cutting grooves may be configured such that a cutting device can cut along the cutting grooves respectively after preparation of all films of the display panel is completed.

In some examples, as shown in FIG. 1, the display region AA may be a planar region including a plurality of sub-pixels PX forming a pixel array, the plurality of sub-pixels PX may be configured to display a dynamic picture or a static image. The display region AA may be referred to as an effective region. In some examples, the display panel may be a flexible panel, and accordingly the display panel may be deformable, for example, may be crimped, bent, folded, or curled.

In some examples, as shown in FIG. 1, the display region AA may at least include a plurality of sub-pixels PX, a plurality of gate lines GL, and a plurality of data lines DL. The plurality of gate lines GL may extend along the first direction X and the plurality of data lines DL may extend along the second direction Y. Orthographic projections of the plurality of gate lines GL on the base substrate may intersect with orthographic projections of the plurality of data lines DL on the base substrate to form a plurality of sub-pixel regions, and one of the sub-pixels PX may be arranged in each sub-pixel region. The plurality of data lines DL are electrically connected with the plurality of sub-pixels PX and the plurality of data lines DL may be configured to provide data signals to the plurality of sub-pixels PX. A plurality of data lines DL may extend to the first bezel region B1. The plurality of gate lines GL are electrically connected with the plurality of sub-pixels PX and the plurality of gate lines GL may be configured to provide gate control signals to the plurality of sub-pixels PX. In some examples, the gate control signal may include a scan signal and a light emitting control signal. As another example, the gate control signal may include a scan signal, a light emitting control signal, and a reset control signal.

In some examples, as shown in FIG. 1, the first direction X may be an extension direction of the gate line GL in the display region AA (row direction), and the second direction Y may be a column direction. The first direction X may intersect with the second direction Y, for example, the first direction X and the second direction Y may be perpendicular to each other.

In some examples, a pixel unit of the display region AA may include three sub-pixels which are a red sub-pixel, a green sub-pixel, and a blue sub-pixel respectively. However, the present embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged side by side horizontally, side by side vertically, or in a manner like a Chinese character “no”. When one pixel unit includes four sub-pixels, the four sub-pixels may be arranged side by side horizontally, side by side vertically, or in a shape of a square. However, the present embodiment is not limited thereto.

In some examples, one sub-pixel may include a pixel circuit and a light emitting element electrically connected with the pixel circuit. The pixel circuit may include a plurality of transistors and at least one capacitor. For example, the pixel circuit may be a circuit of a 3T1C, 4T1C, 5T1C, 5T2C, 6T1C, 7T1C, or 8T1C structure. Herein, in the above circuit structure, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Adopting a same type of transistors in the pixel circuit may simplify a process flow, reduce process difficulties of the display panel, and improve a yield of products. In some other examples, the plurality of transistors in the pixel circuit may include a P-type transistor and an N-type transistor.

In some examples, low temperature poly silicon thin film transistors, or oxide thin film transistors, or both of a low temperature poly silicon thin film transistor and an oxide thin film transistor may be used as the plurality of transistors in the pixel circuit. Low Temperature Poly Silicon (LTPS) is used for an active layer of a low temperature poly silicon thin film transistor and an oxide semiconductor (Oxide) is used for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display panel, that is, an LTPS+Oxide (LTPO for short) display panel, so that advantages of both the low temperature poly silicon thin film transistor and the oxide thin film transistor may be utilized, low-frequency drive may be achieved, power consumption may be reduced, and display quality may be improved.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

FIG. 2 is an equivalent circuit diagram of a pixel circuit according to at least one embodiment of the present disclosure. The pixel circuit of this example is described by taking a 7T1C structure as an example.

In some examples, as shown in FIG. 2, the pixel circuit of this example may include seven transistors (i.e. a first transistor T1 to a seventh transistor T7) and one storage capacitor Cst. The light emitting element EL may include an anode, a cathode and an organic emitting layer arranged between the anode and the cathode.

In some examples, as shown in FIG. 2, the display panel may include a first scan line GL1, a second scan line GL2, a third scan line GL3, a data line DL, a first power supply line VDD, a second power supply line VSS, a light emitting control line EML, a first initial signal line INIT1 and a second initial signal line INIT2.

In some examples, the first power supply line VDD may be configured to provide a constant first voltage signal Vdd to the pixel circuit, and the second power supply line VSS may be configured to provide a constant second voltage signal Vss to the pixel circuit, and the first voltage signal Vdd may be greater than the second voltage signal Vss. The first scan line GL1 may be configured to provide a first scan signal SCAN1 to the pixel circuit, the data line DL may be configured to provide a data signal to the pixel circuit, the light emitting control line EML may be configured to provide a light emitting control signal EM to the pixel circuit, the second scan line GL2 may be configured to provide a second scan signal SCAN2 to the pixel circuit, and the third scan line GL3 may be configured to provide a third scan signal SCAN3 to the pixel circuit.

In some examples, the second scan line GL2 electrically connected to the n-th row of pixel circuits may be electrically connected to the first scan line GL1 electrically connected to the (n−1)-th row of pixel circuits so as to be input with the first scan signal SCAN1 (n−1), that is, the second scan signal SCAN2 (n) may be the same as the first scan signal SCAN1 (n−1). The third scan line GL3 of the n-th row of pixel circuits may be electrically connected to the first scan line GL1 of the n-th row of pixel circuits so as to be input with the first scan signal SCAN1 (n), that is, the third scan signal SCAN3 (n) may be the same as the first scan signal SCAN1 (n). Herein, n is an integer greater than 0. In this way, signal lines of the display panel may be reduced, and a narrow bezel design of the display panel may be achieved. However, the present embodiment is not limited thereto.

In some examples, the first initial signal line INIT1 is configured to provide a first initial signal to the pixel circuit, and the second initial signal line INIT2 is configured to provide a second initial signal to the pixel circuit. For example, the first initial signal may be different from the second initial signal. Herein, the first initial signal and the second initial signal may be constant voltage signals, and the magnitudes of the voltage signals may be between a first voltage signal Vdd and a second voltage signal Vss, but not limited to this. In other examples, the first initial signal and the second initial signal may be the same and only the first initial signal line may be provided to provide the first initial signal.

In some examples, as shown in FIG. 2, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the fourth transistor T4 is electrically connected with the first scan line GL1, a first electrode of the fourth transistor T4 is electrically connected with the data line DL, and a second electrode of the fourth transistor T4 is electrically connected with the first electrode of the third transistor T3. The fourth transistor T4 may be referred to as a data write transistor. A gate of the second transistor T2 is electrically connected with the first scan line GL1, a first electrode of the second transistor T2 is electrically connected with a gate of the third transistor T3, and a second electrode of the second transistor T2 is electrically connected with a second electrode of the third transistor T3. The second transistor T2 may also be referred to as a threshold compensation transistor. A gate electrode of the fifth transistor T5 is electrically connected with the light emitting control line EML, a first electrode of the fifth transistor T5 is electrically connected with the first power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line GL2, a first electrode of the first transistor T1 is electrically connected with a first initial signal line INIT1, and a second electrode of the first transistor T1 is electrically connected with the gate of the third transistor T3. A gate of the seventh transistor T7 is connected with the third scan line GL3, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first electrode plate of the storage capacitor Cst is electrically connected with the gate electrode of the third transistor T3, and a second electrode plate of the storage capacitor Cst is electrically connected with the first power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

A working process of the pixel circuit is explained below. The description is given by taking a case in which a plurality of transistors included in the pixel circuit shown in FIG. 2 are all P-type transistors as an example. In the present example, the third scan signal provided by the third scan line GL3 may be the same as the first scan signal provided by the first scan line GL1.

In some examples, during one-frame display time period, the working process of the pixel circuit may include a first stage, a second stage, and a third stage.

The first stage is referred to as a reset stage. The second scan signal SCAN2 provided by the second scan signal line GL2 may be a low-level signal, so that the first transistor T1 is turned on, and the first initial signal provided by the first initial signal line INIT1 is provided to the first node N1 to initialize the first node N1 and clear an original data voltage in the storage capacitor Cst. The first scan signal SCAN1 provided by the first scan line GL1 may be a high-level signal, and the light emitting control signal EM provided by the light emitting control line EML may be a high-level signal, so that the fourth transistor T4, the second transistor T2, the fifth transistor T5, the sixth transistor T6 and the seventh transistor T7 are turned off. In this stage, the light emitting element EL does not emit light.

The second stage is referred to as a data writing stage or a threshold compensation stage. The first scan signal SCAN1 provided by the first scan line GL1 may be a low-level signal, the second scan signal SCAN2 provided by the second scan line GL2 and the emitting control signal EM provided by the emitting control line EML may be both high-level signals, and the data line DL outputs a data signal DATA. In this stage, since the first electrode plate of the storage capacitor Cst is at a low level, the third transistor T3 is turned on. The first scan signal SCAN1 is the low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first electrode plate (i.e., the first node N1) of the storage capacitor Cst is Vdata−|Vth|, wherein Vdata is the data voltage output by the data line DL, and Vth is the threshold voltage of the third transistor T3. The seventh transistor T7 is turned on, so that a second initial signal provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The second scan signal SCAN2 provided by the second scan line GL2 may be a high-level signal, so that the first transistor T1 is turned off. The light emitting control signal EM provided by the light emitting control signal line EML is a high-level signal, so that the fifth transistor T5 and the sixth transistor T6 are turned off.

The third stage is referred to as a light emitting stage. The light emitting control signal EM provided by the light emitting control line EML is a low-level signal, and the first scan signal SCAN1 provided by the first scan line GL1 and the second scan signal SCAN2 provided by the second scan line GL2 are high-level signals. The light emitting control signal EM provided by the light emitting control line EML is a low-level signal to turn on the fifth transistor T5 and the sixth transistor T6, and the first voltage signal Vdd output from the first power supply line VDD provides a drive voltage to an anode of the light emitting element EL through the fifth transistor T5, the third transistor T3 and the sixth transistor T6 which are turned on to drive the light emitting element EL to emit light.

In a drive process of the pixel circuit, a drive current flowing through the third transistor T3 is determined by a voltage difference between the gate and the first electrode of the third transistor T3. Since the voltage of the first node N1 is Vdata−|Vth|, the drive current of the third transistor T3 is as follows.

$$I = K \times {( V gs - V th )}^{2} = K \times {[ ( V dd - V data + \vert V th \vert ) - V th ]}^{2} = K \times {[ V dd - V data ]}^{2}$$

Herein, I is the drive current flowing through the third transistor T3, that is, a drive current for driving the light emitting element EL, K is a constant, Vgs is the voltage difference between the gate electrode and the first electrode of the third transistor T3, Vth is the threshold voltage of the third transistor T3, Vdata is the data voltage outputted by the data line DL, and Vdd is the first voltage signal outputted by the first power supply line VDD.

It may be seen from the above formula that a current flowing through the light emitting element EL is independent of the threshold voltage of the third transistor T3. Therefore, the pixel circuit according to this embodiment may better compensate the threshold voltage of the third transistor T3.

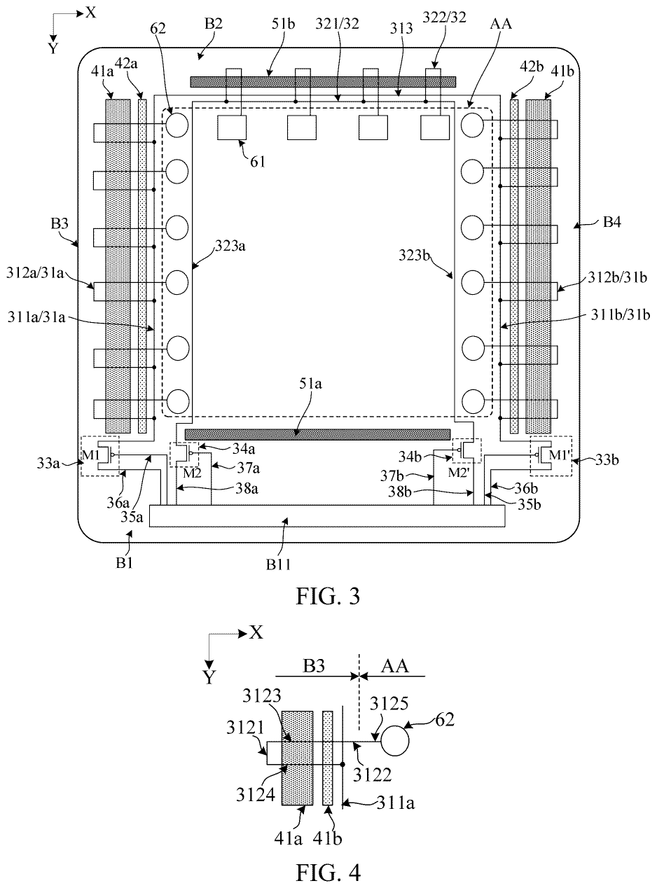

FIG. 3 is a schematic diagram of a display panel according to at least one embodiment of the present disclosure. In some examples, as shown in FIG. 3, at least one sub-pixel of the display region AA may include a pixel circuit 61 and a light emitting element 62. The light emitting element 62 may be located on a side of the pixel circuit 61 away from the base substrate. The pixel circuit 61 is electrically connected to the light emitting element 62 and may be configured to drive the corresponding light emitting element 62 to emit light. An orthographic projection of the light emitting element 62 on the base substrate may be at least partially overlapped with an orthographic projection of a connected pixel circuit 61 on the base substrate. FIG. 3 is illustrated by taking a plurality of pixel circuits 61 and a plurality of light emitting elements 62 as an example, and there may be no electrical connection relationship between the pixel circuit 61 and the light emitting element 62 illustrated in FIG. 3. In the present example, a plurality of light emitting elements 62 sequentially arranged along the first direction X may be referred to as a row of light emitting elements, a plurality of pixel circuits 61 sequentially arranged along the first direction X may be referred to as a row of pixel circuits, a plurality of pixel circuits 61 sequentially arranged along the second direction Y may be referred to as a column of light emitting elements, and a plurality of light emitting elements 62 sequentially arranged along the second direction Y may be referred to as a column of light emitting elements.

In some examples, as shown in FIG. 3, the first bezel region B1 may include a signal access region B11. The signal access region B11 may be configured to provide an integrated circuit, for example, the integrated circuit may be a Display Driver Integration (DDI for short) circuit or a Touch and Display Driver Integration (TDDI for short) circuit.

In some examples, as shown in FIG. 3, the first bezel region B1 may be provided with first detection control units 33a and 33b, second detection control units 34a and 34b, and a first power supply bezel line 51a. The first power supply bezel line 51a may extend at least along the first direction X and is located on a side of the signal access region B11 close to the display region AA in the second direction Y. The first power supply bezel line 51a may be electrically connected to a plurality of first power supply lines extending along the second direction Y in the display region AA and is configured to supply first voltage signals to the plurality of first power supply lines.

In some examples, as shown in FIG. 3, the first detection control unit 33a and the second detection control unit 34a may be located at a position within the first bezel region B1 close to the third bezel region B3, and the first detection control unit 33b and the second detection control unit 34b may be located at a position within the first bezel region B close to the fourth bezel region B4. The first detection control unit 33a and the first detection control unit 33b, and the second detection control unit 34a and the second detection control unit 34b may be located on a side of the signal access region B11 close to the display region AA. The first detection control unit 33a may be located on a side of the second detection control unit 34a close to an edge of the display panel in the first direction X, and the first detection control unit 33b may be located on a side of the second detection control unit 34b close to the edge of the display panel in the first direction X.

In some examples, as shown in FIG. 3, the first detection control unit 33a may include a first detection transistor M1. A gate of the first detection transistor M1 may be electrically connected to a first detection control line 35a, a first electrode of the first detection transistor M1 is electrically connected to a first test signal transmission line 36a, and a second electrode of the first detection transistor M1 is electrically connected to a first detection line 31a. The first detection control line 35a may extend to the signal access region B11 and is electrically connected to a first detection control pin within the signal access region B11. The first test signal transmission line 36a may extend to the signal access region B11 and is electrically connected to a first test signal pin within the signal access region B11.

In some examples, as shown in FIG. 3, the first detection control unit 33b may include a first detection transistor M1′. A gate of the first detection transistor M1′ may be electrically connected to a first detection control line 35b, a first electrode of the first detection transistor M1′ is electrically connected to a first test signal transmission line 36b, and a second electrode of the first detection transistor M1′ is electrically connected to a first detection line 31b. The first detection control line 35b may extend to the signal access region B11 and is electrically connected to another first detection control pin within the signal access region B11. The first test signal transmission line 36b may extend to the signal access region B11 and is electrically connected to another first test signal pin within the signal access region B11. The first detection control pins transmitting the same first detection control signal within the signal access region B11 may be electrically connected to each other, and the first test signal pins transmitting the same first test signal may be electrically connected to each other.

In some examples, as shown in FIG. 3, the second detection control unit 34a may include a second detection transistor M2. A gate of the second detection transistor M2 may be electrically connected to a second detection control line 37a, a first electrode of the second detection transistor M2 is electrically connected to a second test signal transmission line 38a, and a second electrode of the second detection transistor M2 is electrically connected to a second detection line 32. The second detection control line 37a may extend to the signal access region B11 and is electrically connected to a second detection control pin within the signal access region B11. The second test signal transmission line 38a may extend to the signal access region B11 and is electrically connected to a second test signal pin within the signal access region B11.

In some examples, as shown in FIG. 3, the second detection control unit 34b may include a second detection transistor M2′. A gate of the second detection transistor M2′ may be electrically connected to a second detection control line 37b, a first electrode of the second detection transistor M2′ is electrically connected to a second test signal transmission line 38b, and a second electrode of the second detection transistor M2′ is electrically connected to a second detection line 32. The second detection control line 37b may extend to the signal access region B11 and is electrically connected to another second detection control pin within the signal access region B11. The second test signal transmission line 38a may extend to the signal access region B11 and is electrically connected to another second test signal pin within the signal access region B11. The second detection control pins transmitting the same second detection control signal within the signal access region B11 may be electrically connected to each other, and the second test signal pins transmitting the same second test signal may be electrically connected to each other.

In some examples, as shown in FIG. 3, the third bezel region B3 may be provided with a gate drive circuit 41a, a bezel initial signal line 42a, and a first detection line 31a. The gate drive circuit 41a may include, for example, a scan drive circuit, and the scan drive circuit may include a plurality of scan shift registers arranged along the second direction Y, and may be configured to provide scan signals to a plurality of scan lines of the display region AA (for example, provide first scan signals to a plurality of first scan lines GL1, provide second scan signals to a plurality of second scan lines GL2, and provide third scan signals to a plurality of third scan lines GL3). The bezel initial signal line 42a may be located on a side of the gate drive circuit 41a close to the display region AA. For example, the bezel initial signal line 42a may include a first bezel initial signal line transmitting a first initial signal or may include a first bezel initial signal line transmitting a first initial signal and a second bezel initial signal line transmitting a second initial signal.

In some examples, as shown in FIG. 3, the first detection line 31a may include a first main line 311a and a plurality of first sub-lines 312a. FIG. 3 is illustrated by taking six first sub-lines 312a as an example, and the number of first sub-lines 312a is not limited in the present embodiment. A plurality of first sub-lines 312a are electrically connected to the first main line 311a. The first main line 311a may extend at least along the second direction Y. The plurality of first sub-lines 312a may be arranged sequentially along the second direction Y. The first main line 311a may be located on a side of the gate drive circuit 41a and the bezel initial signal line 42a close to the display region AA. For example, the first main line 311a may be located on a side of the bezel initial signal line 42a away from the gate drive circuit 41a. A portion of a line segment of each first sub-line 312a may be located on a side of the gate drive circuit 41a away from the display region AA. For example, a portion of the line segment of each first sub-line 312a may be located in a power supply line region of the third bezel region B3 and located on a side of a low-level power supply line away from the display region AA. After being connected to the first main line 311a, each first sub-lines 312a may extend along the first direction X to a side away from the display region AA until passing through the gate drive circuit 41a, then wind and extend along the first direction X to a side close to the display region AA, and finally extend to be electrically connected to an anode of a light emitting element 62 of one sub-pixel in the display region AA. In this example, the first sub-line 312a is designed to be wound at an edge of a side away from the first main line 311a, which may facilitate accurate locating an edge crack position of the third bezel region B3, thereby improving the working efficiency.

FIG. 4 is a schematic diagram of a partial wiring of a display panel according to at least one embodiment of the present disclosure. FIG. 4 illustrates a winding mode of a first sub-line. In some examples, as shown in FIGS. 3 and 4, the first sub-line 312a may include at least a first line segment 3121, a second line segment 3122, a first cross-line 3123, a second cross-line 3124, and a first connection segment 3125. The second cross-line 3124, the first line segment 3121, the first cross-line 3123, the second line segment 3122, and the first connection segment 3125 may be electrically connected sequentially. The second cross-line 3124 may be electrically connected to the first main line 311a, and the first connection segment 3125 may be electrically connected to an anode of a light emitting element 62 of a sub-pixel of the display region AA. For example, the first cross-line 3123 and the second cross-line 3124 may extend at least along the first direction X, the first line segment 3121 may extend at least along the second direction Y, and the second line segment 3122 and the first connection segment 3125 may extend at least along the first direction X. In this example, a portion of the line segment of the first sub-line 312a located on a side of the gate drive circuit 41a away from the display region AA may include the first line segment 3121.

In some examples, as shown in FIGS. 3 and 4, orthographic projections of the first cross-line 3123 and the second cross-line 3124 on the base substrate may be overlapped with orthographic projections of the gate drive circuit 41a and the bezel initial signal line 42a on the base substrate, and orthographic projections of the first line segment 3121 and the second line segment 3122 on the base substrate may be not overlapped with the orthographic projections of the gate drive circuit 41a and the bezel initial signal line 42a on the base substrate. The first line segment 3121 may be located on a side of the gate drive circuit 41a away from the display region AA, and the second line segment 3122 and the first connection segment 3125 may be located on a side of the bezel initial signal line 42a close to the display region AA. For example, the first cross-line 3123 and the second cross-line 3124 may be of the same layer structure, the first line segment 3121 and the second line segment 3122 may be of the same layer structure, and the first connection segment 3125 and the second line segment 3122 may be located in different films.

In some examples, as shown in FIGS. 3 and 4, the first cross-line 3123, the first line segment 3121 and the second cross-line 3124 of the first sub-line 312a may form an inflexion portion. However, the present embodiment is not limited thereto. In other examples, the first sub-line may be a serpentine line and have a plurality of inflexion portions. The serpentine line is a bending curve. For example, after one end of the line extends along one direction for a certain distance, it bends circuitously and extends along a direction opposite to this direction for a certain distance, and bends circuitously again and extends along this direction. In this way, circuitous bending is repeated for several times to form the serpentine line.

In some examples, as shown in FIG. 3, the plurality of first sub-lines 312a of the first detection line 31a may be electrically connected to the light emitting elements 62 of the plurality of sub-pixels in one-to-one correspondence. The light emitting elements 62 of the plurality of sub-pixels to which the first detection line 31a is connected may be arranged in a column, for example, the light emitting elements 62 of the plurality of sub-pixels to which the first detection line 31a is connected may include a column of light emitting elements 62 closest to the third bezel region B3. Each first sub-line 312a of the first detection line 31a may be independently electrically connected to one light emitting element 62. In the present example, each first sub-line 312a is arranged to be independently electrically connected to the light emitting element 62, which may facilitate accurately locating an edge crack position of the third bezel region B3 according to whether the light emitting element 62 is lit.

In some examples, as shown in FIG. 3, the fourth bezel region B4 may be provided with a gate drive circuit 41b, a bezel initial signal line 42b, and a first detection line 31b. The gate drive circuit 41b may include, for example, a light emitting drive circuit, which may include a plurality of light emitting shift registers arranged along the second direction Y, and may be configured to provide light emitting control signals to a plurality of light emitting control lines of the display region AA. The bezel initial signal line 42b may be located on a side of the gate drive circuit 41b close to the display region AA. The bezel initial signal line 42a and the bezel initial signal line 42b may be electrically connected to each other.

In some examples, as shown in FIG. 3, the first detection line 31b may include a first main line 311b, and a plurality of first sub-lines 312b. FIG. 3 is illustrated by taking six first sub-lines 312b as an example, and the number of first sub-lines 312b is not limited in the present embodiment. A plurality of first sub-lines 312b is electrically connected to the first main line 311b. The first main line 311b may extend at least along the second direction Y. The first main line 311b may be located on a side of the gate drive circuit 41b and the bezel initial signal line 42b close to the display region AA. For example, the first main line 311b may be located on a side of the bezel initial signal line 42b away from the gate drive circuit 41b. Partial line segment of each first sub-line 312b may be located on a side of the gate drive circuit 41b away from the display region AA. For example, partial line segment of each first sub-line 312b may be located in a power supply line region of the fourth bezel region B4 and located on a side of a low-level power supply line away from the display region AA. After being connected to the first main line 311b, each first sub-line 312b may extend along the first direction X to a side away from the display region AA until passing through the gate drive circuit 41b, then wind and extend along the first direction X to a side close to the display region AA, and finally extend to be electrically connected to an anode of a light emitting element 62 of one sub-pixel in the display region AA. In this example, the first sub-line 312b is designed to be wound at an edge of a side away from the first main line 311b, which may facilitate accurate locating an edge crack position of the fourth bezel region B4, thereby improving the working efficiency. The winding design of the first sub-wire 312b may refer to the description of the first sub-wire 312a, and thus will not be repeated here.

In some examples, as shown in FIG. 3, the light emitting elements 62 of the plurality of sub-pixels to which the first detection line 31b is connected may be arranged in a column, which may include, for example, a column of light emitting elements 62 closest to the fourth bezel region B4. Each first sub-line 312b of the first detection line 31b may be independently electrically connected to one light emitting element 62. In the present example, each first sub-line 312b is arranged to be independently electrically connected to the light emitting element 62, which may facilitate accurately locating an edge crack position of the fourth bezel region B4 according to whether the light emitting element 62 is lit.

In some examples, as shown in FIG. 3, the second bezel region B2 may be provided with a first power supply bezel line 51, and a second detection line 32. The first power supply bezel line 51b may extend at least along the first direction X. The first power supply bezel line 51b may be electrically connected with a plurality of first power supply lines extending along the second direction Y within the display region AA.

In some examples, as shown in FIG. 3, the second detection line 32 may include a second main line 321, and a plurality of second sub-lines 322. FIG. 3 is illustrated by taking four second sub-lines 322 as an example, and the number of second sub-lines 322 is not limited in the present embodiment. A plurality of second sub-lines 322 are electrically connected to the second main line 321. The second main line 321 may extend at least along the first direction X. The plurality of second sub-lines 322 may be arranged sequentially along the first direction X. The second main line 321 may be located on a side of the first power supply bezel line 51b close to the display region AA. Partial line segment of each second sub-line 322 may be located on a side of the first power supply bezel line 51b away from the display region AA. After being connected to the second main line 321, each second sub-line 322 may extend along the second direction Y to a side away from the display region AA until passing through the first power supply bezel line 51b, then is wound and extend along the second direction Y to a side close to the display region AA, and finally extend to be electrically connected to a pixel circuit 61 of one sub-pixel within the display region AA.

FIG. 7 is a schematic diagram of another partial wiring of a display substrate according to at least one embodiment of the present disclosure. FIG. 7 illustrates a winding mode of a second sub-wire 322. In some examples, as shown in FIGS. 3 and 7, the second sub-line 322 may at least include a third line segment 3221, a fourth line segment 3222, a third cross-line 3223, a fourth cross-line 3224, and a second connection segment 3225. The fourth cross-line 3224, the third line segment 3221, the third cross-line 3223, the fourth line segment 3222, and the second connection segment 3225 may be electrically connected sequentially. The fourth cross-line 3224 may be electrically connected to the second main line 321, and the second connection segment 3225 may be electrically connected to a pixel circuit 61 of a sub-pixel of the display region AA. For example, the third cross-line 3223 and the fourth cross-line 3224 may at least extend along the second direction Y, the third line segment 3221 may at least extend along the first direction X, and the fourth line segment 3222 and the second connection segment 3225 may extend along the second direction Y. In this example, partial line segments of the second sub-line 322 located on a side of the first power supply bezel line 51b away from the display region AA may include a third line segment 3221.

In some examples, as shown in FIGS. 3 and 7, orthographic projections of the third cross-line line 3223 and the fourth cross-line line 3224 on the base substrate may be overlapped with an orthographic projection of the first power supply bezel line 51b on the base substrate, and orthographic projections of the third line segment 3221 and the fourth line segment 3222 on the base substrate may be not overlapped with the orthographic projection of the first power supply bezel line 51b on the base substrate. The third line segment 3221 may be located on a side of the first power supply bezel line 51b away from the display region AA, and the fourth line segment 3222 and the second connection segment 3225 may be located on a side of the first power supply bezel line 51b close to the display region AA. For example, the third cross-line 3223 and the fourth cross-line 3224 may be of the same layer structure, the third line segment 3221 and the fourth line segment 3222 may be of the same layer structure, and the second connection segment 3225 and the fourth line segment 3222 may be located in different films.

In some examples, as shown in FIGS. 3 and 7, the third cross-line 3223, the third line segment 3221 and the fourth cross-line 3224 of the second sub-line 322 may form an inflexion portion. However, the present embodiment is not limited thereto. In other examples, the second sub-line may be a serpentine line and have a plurality of inflexion portions.

In some examples, as shown in FIG. 3, the plurality of second sub-lines 322 of the second detection line 32 may be electrically connected to pixel circuits 61 of a plurality of sub-pixels in one-to-one correspondence. The pixel circuits 61 of the plurality of sub-pixels to which the second detection line 32 is connected may be arranged in a row, for example, the pixel circuits 61 to which the second detection line 32 is connected may include pixel circuits in a row of pixel circuits 61 closest to the second bezel region B2 except the first pixel circuit and the last pixel circuit. The first pixel circuit in the row of pixel circuits may be electrically connected to one of a column of light emitting elements closest to the third bezel region B3, and the last pixel circuit in the row of pixel circuits may be electrically connected to one of a column of light emitting elements closest to the fourth bezel region B4. A sub-pixel connected to the first detection lines 31a and 31b of the present example is different from a sub-pixel connected to the second detection line 32, so as to avoid mutual influence of detection effects between the first detection lines 31a and 31b and the second detection line 32.

In some examples, as shown in FIG. 3, each second sub-line 322 of the second detection line 32 may be electrically connected to a source electrode of a data write transistor of one pixel circuit 61 (e.g. a fourth transistor T4 in the aforementioned pixel circuit). Each second sub-line 322 may be independently electrically connected to the data write transistor of the pixel circuit 61. In this example, each second sub-line 322 is arranged to be independently electrically connected to the data write transistor of the pixel circuit 61, which may facilitate accurately locating a crack position of the edge of the second bezel region B2 according to whether the light emitting element connected to the pixel circuit 61 is lit.

In some examples, as shown in FIG. 3, the second bezel region B2 may further be provided with a first connection line 313. The first detection line 31a within the third bezel region B3 may be electrically connected to the first detection line 31b within the fourth bezel region B4 through the first connection line 313. Both ends of the first connection line 313 may be electrically connected to a first main line 311a of the first detection line 31a and a first main line 311b of the first detection line 31b, respectively. The first connection line 313 may be located on a side of the first power supply bezel line 51b close to the display region AA, which may be located, for example, on a side of the second main line 321 of the second detection line 32 close to the first power supply bezel line 51b. However, the present embodiment is not limited thereto. In this example, the first detection line 31a within the third bezel region B3 are electrically connected with the first detection line 31b within the fourth bezel region B4 through the first connection line 313, so that the first test signal may be transmitted around the third bezel region B3, the second bezel region B2 and the fourth bezel region B4, which is beneficial to the wiring in the peripheral region and edge crack detection in the peripheral region.

In some examples, as shown in FIG. 3, the display region AA may further be provided with second connection lines 323a and 323b. One end of the second main line 321 of the second detection line 32 of the second bezel region B2 may be electrically connected to the second connection line 323a, and is electrically connected to the second detection control unit 34a through the second connection line 323a. The other end of the second main line 321 may be electrically connected to the second connection line 323b, and is electrically connected to the second detection control unit 34b through the second connection line 323b. By arranging the second connection lines 323a and 323b to be in the display region, it is possible to avoid the influence of wire arrangement in the third bezel region B3 and the fourth bezel region B4 on the transmission of the second test signal.

FIG. 6 is a schematic partial sectional view of a display region according to at least one embodiment of the present disclosure. FIG. 6 is illustrated by taking two sub-pixels of the display region as an example. In some examples, as shown in FIG. 6, in a direction perpendicular to the display panel, the display region of the display panel may at least include a base substrate 10, and a circuit structure layer 12, a light emitting structure layer 13, and an encapsulation structure layer 14, which are arranged on the base substrate 10. The circuit structure layer 12 may include a Barrier layer 101, a Bottom Shielding Metal (BSM) layer, a Buffer layer 102, a semiconductor layer, a first gate insulation layer 103, a first gate metal layer, a second gate insulation layer 104, a second gate metal layer, an interlayer insulation (ILD) layer 105, a first source-drain metal layer, a first planarization (PLN) layer 106, a second source-drain metal layer, and a second planarization layer 107, which are sequentially arranged on the base substrate 10. The circuit structure layer 12 in FIG. 6 is illustrated by taking that one transistor 21 (e.g. the sixth transistor in the pixel circuit of the aforementioned embodiment) and one first capacitor 22 (e.g. a storage capacitor in the pixel circuit of the aforementioned embodiment) are included in each sub-pixel as an example. Herein, the barrier layer 101, the buffer layer 102, the first gate insulation layer 103, the second insulation layer 104, and the interlayer insulation layer 105 may be inorganic insulation layers, and the first planarization layer 106 and the second planarization layer 107 may be organic insulation layers. The barrier layer 101 and the buffer layer 102 may prevent harmful substances in the base substrate 10 from intruding into the interior of the display panel and may also increase adhesion of the film layer in the display panel on the base substrate 10. However, the present embodiment is not limited thereto. In other examples, a passivation layer may be provided between the first source-drain metal layer and the second source-drain metal layer, and the passivation layer may be located on a side of the first planarization layer close to the base substrate.

In some examples, the barrier layer 101, the buffer layer 102, the first gate insulation layer 103, the second insulation layer 104 and the interlayer insulation layer 105 may be made of any one or more of silicon oxide (SiOx, x>0), silicon nitride (SiNx, y>0) and silicon oxynitride (SiON), and may be a single layer, multiple layers or a composite layer. The first planarization layer 106 and the second planarization layer 107 may be made of an organic material, such as polyimide, acrylic, or polyethylene terephthalate. The bottom shielding metal layer, the first gate metal layer and the second gate metal layer may be made of a metal material, such as any one or more of silver (Ag), copper (Cu), aluminum (Al), titanium (Ti), and molybdenum (Mo), and may be of a single-layered structure. The first source-drain metal layer and the second source-drain metal layer may be made of a metal material, such as any one or more of silver (Ag), copper (Cu), aluminum (Al), titanium (Ti) and molybdenum (Mo), or an alloy material of the aforementioned metals, such as an aluminum neodymium alloy (AlNd) or a molybdenum niobium alloy (MoNb), and each of them may be of a single-layered structure or a multi-layered composite structure, such as Ti/Al/Ti. The semiconductor layer may be made of one or more materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), hexathiophene, and polythiophene. That is, the present disclosure is applicable to a transistor manufactured based on an oxide technology, a silicon technology, and an organic matter technology. The present embodiment is not limited thereto.

In some examples, as shown in FIG. 6, the bottom shielding metal layer of the display region may be configured to at least partially cover an active layer of a transistor of the pixel circuit to avoid the influence of external light on the performance of the transistor. For example, the bottom shielding metal layer may at least include a bottom shielding block 20, an orthographic projection of the bottom shielding block 20 on the base substrate 10 may cover an orthographic projection of a channel region of the active layer 210 of the transistor 21 on the base substrate 10.

In some examples, as shown in FIG. 6, the semiconductor layer of the display region may include at least an active layer 210 of the transistor 21. The active layer 210 of a transistor 21 may include a first region, a second region, and a channel region located between the first region and the second region. The first gate metal layer may at least include a gate 213 of the transistor 21, and a first electrode plate 221 of the first capacitor 22. An orthographic projection of the gate 213 of the transistor 21 on the base substrate 10 may cover an orthographic projection of the channel region of the active layer 210 on the base substrate 10. The second gate metal layer may at least include a second electrode plate 222 of the first capacitor 22. Orthographic projections of the second electrode plate 222 and the first electrode plate 221 of the first capacitor 22 on the base substrate 10 may be at least partially overlapped, for example, the two may coincide. The first source-drain metal layer may at least include a source 211 and a drain electrode 212 of the transistor 21. The interlayer insulation layer 105 may be provided with a plurality of via holes (for example, including a first pixel via hole and a second pixel via hole) in the display region, and the interlayer insulation layer 103, the second gate insulation layer 102 and the first gate insulation layer 101 in the first pixel via hole may be removed to expose at least portion of a surface of the first region of the active layer 210; the interlayer insulation layer 103, the second gate insulation layer 102, and the first gate insulation layer 101 within the second pixel via hole may be removed to expose at least portion of a surface of the second region of the active layer 210. The source electrode 211 of the transistor 21 may be electrically connected to the first region of the active layer 210 through the first pixel via hole, and the drain electrode 212 may be electrically connected to the second region of the active layer 210 through the second pixel via hole. The second source-drain metal layer may at least include a first transfer electrode 23. The first transfer electrode 23 may be electrically connected to the drain electrode 212 of the transistor 21 of the pixel circuit through a third pixel via hole opened in the first planarization layer 106. The first transfer electrode 23 may be electrically connected to the first electrode 131 (e.g. an anode) of the light emitting element through a fourth pixel via hole opened in the second planarization layer 107. In this example, an electrical connection between the pixel circuit and the light emitting element may be achieved through the first transfer electrode 23.

In some examples, as shown in FIG. 6, the light emitting structure layer 13 of the display region may include a pixel definition layer 134 and a plurality of light emitting elements. For example, each light emitting element may include a first electrode 131, an organic light emitting layer 132 and a second electrode 133 which are stacked. The first electrode 131 of the light emitting element may be an anode, the first electrode 131 may be provided on the second planarization layer 107 and electrically connected to the first transfer electrode 23 through the fourth pixel via hole opened in the second planarization layer 107. The pixel definition layer 134 is provided on the first electrode 131 and the second planarization layer 107, and may be provided with a plurality of pixel openings, one pixel opening may expose at least portion of a surface of a corresponding first electrode 131. At least portion of the organic light emitting layer 132 may be arranged within one pixel opening and connected to a corresponding first electrode 131. The second electrode 133 may be arranged on the organic light emitting layer 132 and be connected to the organic light emitting layer 132. The organic light emitting layer 132 may be driven by the first electrode 131 and the second electrode 133 to emit light of a corresponding color. A post spacer layer may be provided on a side of the pixel definition layer 134 away from the base substrate 10, and the post spacer layer may include a plurality of post spacers (PS) 135.

In some examples, as shown in FIG. 6, the organic light emitting layer 132 of the light emitting element of the display region may include an Emitting Layer (EML for short), and include one or more film layers of a Hole Injection Layer (HIL for short), a Hole Transport Layer (HTL for short), a Hole Block Layer (HBL for short), an Electron Block Layer (EBL for short), an Electron Injection Layer (EIL for short), and an Electron Transport Layer (ETL for short). When driven by voltages of the first electrode 131 and the second electrode 133, light may be emitted according to a required gray scale, in virtue of light emitting characteristics of an organic material.

In some examples, light emitting layers of light emitting elements in different colors may be different. For example, a red light emitting element includes a red light emitting layer, a green light emitting element includes a green light emitting layer, and a blue light emitting element includes a blue light emitting layer. In order to reduce a process difficulty and improve a yield, a hole injection layer and a hole transport layer located on a side of a light emitting layer may be a common layer, and an electron injection layer and an electron transport layer located on another side of the light emitting layer may be a common layer. In some examples, any one or more layers of the hole injection layer, the hole transport layer, the electron injection layer, and the electron transport layer may be made in one process (one evaporation process or one inkjet printing process), and isolation may be achieved by means of a formed film layer surface segment difference or by means of a surface treatment. For example, any one or more of hole injection layers, hole transport layers, electron injection layers, and electron transport layers corresponding to adjacent sub-pixels may be isolated. In some examples, the organic light emitting layer may be manufactured and formed through evaporation using a Fine Metal Mask (FMM for short) or an open mask, or manufactured and formed using an inkjet process.

In some examples, as shown in FIG. 6, the encapsulation structure layer 14 may include a first encapsulation layer 141, a second encapsulation layer 142, and a third encapsulation layer 143 which are stacked. The first encapsulation layer 141 and the third encapsulation layer 143 may be made of an inorganic material, the second encapsulation layer 142 may be made of an organic material, and the second encapsulation layer 142 is disposed between the first encapsulation layer 141 and the third encapsulation layer 143 to ensure that external water vapor cannot enter the light emitting element. However, the present embodiment is not limited thereto. For example, an encapsulation structure layer may be of a five-layer stacked structure of inorganic/organic/inorganic/organic/inorganic.

In some examples, as shown in FIG. 6, the display panel may include a touch structure layer 15 and a color filter layer 16 located on a side of the encapsulation structure layer 14 away from the base substrate 10. The color filter layer 16 may be located on a side of the touch structure layer 15 away from the encapsulation structure layer 14. The color filter layer 16 may include a plurality of filter units of different colors (e.g. including filter units 163), black matrixes 162 located between different filter units, a color film buffer layer (CBL) 161 located on a side of the black matrixes 162 and the plurality of filter units close to the base substrate 10, and a color film protection layer (COC) 164 located on a side of the black matrixes 162 and the plurality of filter units away from the base substrate 10. In some examples, the plurality of filter units of the color filter layer 16 may include a plurality of red filter units, a plurality of green filter units and a plurality of blue filter units. The filter units of different colors may correspond to light emitting elements emitting different colors in the light emitting structure layer 13. For example, a blue filter unit may correspond to a blue light emitting element, an orthographic projection of the blue filter unit on the base substrate may be at least partially overlapped with an orthographic projection of a light emitting region of the blue light emitting element on the base substrate, for example, the orthographic projection of the blue filter unit on the base substrate may cover the orthographic projection of the light emitting region of the blue light emitting element on the base substrate. In the present example, the filter unit can make light of a single color pass through and absorb light of other colors. For example, a blue filter unit can let blue light pass through and absorb light of other colors.

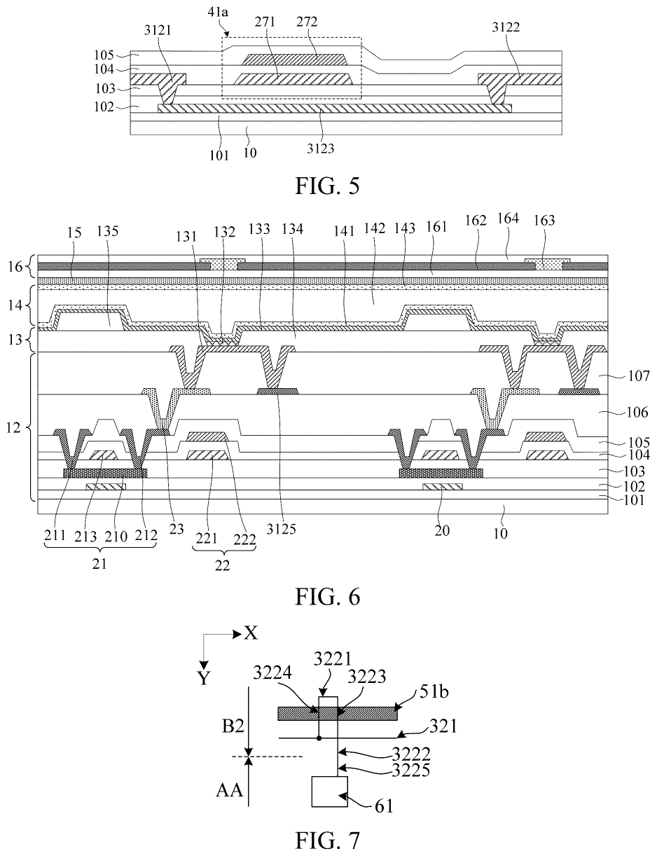

FIG. 5 is a schematic partial sectional view of the first sub-line shown in FIG. 4. In some examples, as shown in FIGS. 3 to 6, the first line segment 3121 and the second line segment 3122 of the first sub-line 312a may be located in the first gate metal layer, the first cross-line 3123 and the second cross-line 3124 may be located in the bottom shielding metal layer, and the first connection segment 3125 may be located, for example, in the second source-drain metal layer. The first line segment 3121 may be electrically connected to one end of the first cross-line line 3123 through a first connection via hole opened in the first gate insulation layer 103 and the buffer layer 102, and the first cross-line line 3123 may extend from the underneath of the gate drive circuit 41a and the bezel initial signal line 42a to cross the gate drive circuit 41a and the bezel initial signal line 42a. The gate drive circuit 41a may include, for example, a second capacitor which may include a first electrode plate 271 located in the first gate metal layer and a second electrode plate 272 located in the second gate metal layer. The connection position between the first line segment 3121 and the first cross-line line 3123 may be located on a side of the gate drive circuit 41a away from the display region. The other end of the first cross-line line 3123 may be electrically connected to the second line segment 3122 through a second connection via hole opened in the first gate insulation layer 103 and the buffer layer 102. The connection position between the first cross-line line 3123 and the second line segment 3122 may be located on a side of the gate drive circuit 41a and the bezel initial signal line 42a close to the display region. The second line segment 3122 may be electrically connected to the first connection segment 3125, for example, the first connection segment 3125 may be electrically connected to the second line segment 3122 located in the first gate metal layer through a third connection via hole opened in the second planarization layer 107, the first planarization layer 106, the interlayer insulation layer 105 and the second gate insulation layer 104.

In some examples, as shown in FIG. 6, after extending to the display region, the first connection segment 3125 may be electrically connected to the anode 131 of a light emitting element within the display region close to the third bezel region. The anode 131 of the light emitting element may be electrically connected to the first connection segment 3125 through a fourth connection via hole opened in the second planarization layer 107, thereby achieving an electrical connection between the anode 131 of the light emitting element and the first sub-line 312a.

In this example, the first cross-line line 3123 and the second cross-line line 3124 arranged in the bottom shielding metal layer are used to make the first sub-line jump wire in a region where the gate drive circuit and the bezel initial signal line are located, so that the influence of the first sub-line on the gate drive circuit and the bezel initial signal line may be avoided, and the layout of the lines is convenient, which is beneficial to saving space.

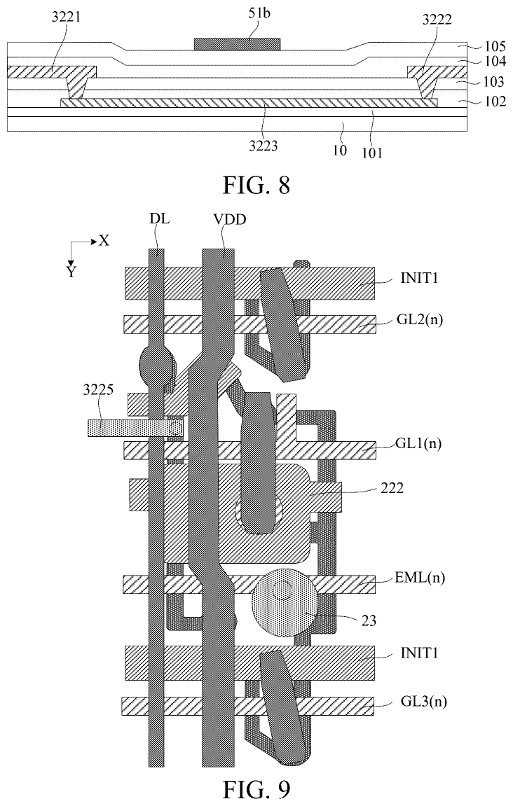

FIG. 8 is a schematic partial sectional view of the second sub-line shown in FIG. 7. In some examples, as shown in FIGS. 3, 7 and 8, the third line segment 3221 and the fourth line segment 3222 of the second sub-line 322 may be located in the first gate metal layer, and the third cross-line line 3223 and the fourth cross-line line 3224 may be located in the bottom shielding metal layer. The second connection segment 3225 may be, for example located in the second source-drain metal layer. The first power supply bezel line 51b may be, for example, located in the first source-drain metal layer.

In some examples, as shown in FIGS. 7 and 8, the third line segment 3221 of the second sub-line 322 may be electrically connected to one end of the third cross-line line 3223 through a fifth connection via hole opened in the first gate insulation layer 103 and the buffer layer 102, and the third cross-line line 3223 may extend from the underneath of the first power supply bezel line 51b to cross the first power supply bezel line 51b. The connection position between the third line segment 3221 and the third cross-line line 3223 may be located on a side of the first power supply bezel line 51b away from the display region. The other end of the third cross-line 3223 may be electrically connected to the fourth line segment 3222 through a sixth connection via hole opened in the first gate insulation layer 103 and the buffer layer 102. The connection position between the third cross-line line 3223 and the fourth line segment 3222 may be located on a side of the first power supply bezel line 51b close to the display region AA. The fourth line segment 3222 may be electrically connected to the second connection segment 3225, for example, the second connection segment 3225 may be electrically connected to the fourth line segment 3222 located in the first gate metal layer through a seventh connection via hole opened in the second planarization layer 107, the first planarization layer 106, the interlayer insulation layer 105 and the second gate insulation layer 104.

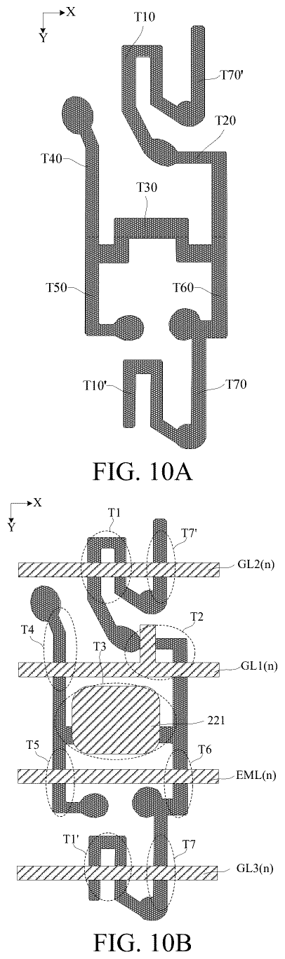

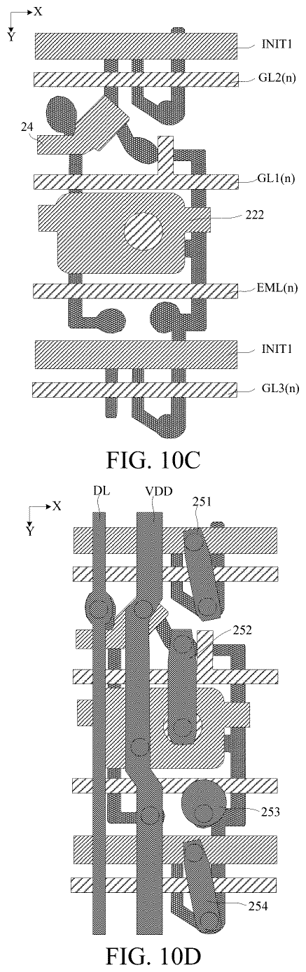

FIG. 9 is a schematic diagram of a connection between a second sub-line and a pixel circuit according to at least one embodiment of the present disclosure. FIG. 10A is a schematic diagram of a pixel circuit after a semiconductor layer is formed in FIG. 9. FIG. 10B is a schematic diagram of a pixel circuit after a first gate metal layer is formed in FIG. 9. FIG. 10C is a schematic diagram of a pixel circuit after a second gate metal layer is formed in FIG. 9. FIG. 10D is a schematic diagram of a pixel circuit after a source-drain metal layer is formed in FIG. 9. The pixel circuit of the present example may be the 7T1C pixel circuit shown in the aforementioned embodiment.

In some examples, as shown in FIG. 10A, the semiconductor layer of the display region may include active layers of a plurality of transistors of a pixel circuit (including, for example, an active layer T10 of the first transistor, an active layer T20 of the second transistor, an active layer T30 of the third transistor, an active layer T40 of the fourth transistor, an active layer T50 of the fifth transistor, an active layer T60 of the sixth transistor and an active layer T70 of the seventh transistor of the present row of pixel circuits, an active layer T70′ of the seventh transistor of the previous row of pixel circuits, and an active layer T10′ of the first transistor of the next row of pixel circuits). The active layers of the seven transistors of a pixel circuit may be of an integral structure in which the active layers are connected with each other.

In some examples, as shown in FIG. 10B, the first gate metal layer of the display region may at least include a first scan line GL1 (n), a second scan line GL2 (n), a third scan line GL3 (n), and a light emitting control line EML (n). The second scan line GL2 (n) may serve as a gate of the first transistor T1 of the present row of pixel circuits and a gate of the seventh transistor T7′ of the previous row of pixel circuits at the same time. The first scan line GL1 (n) may serve as a gate of the second transistor T2 and a gate of the fourth transistor T4 of the present row of pixel circuits at the same time. The third scan line GL3 (n) may serve as a gate of the seventh transistor T7 of the present row of pixel circuits and a gate of the first transistor T1′ of the next row of pixel circuits at the same time. The light emitting control line EML (n) may serve as a gate of the fifth transistor T5 and a gate of the sixth transistor T6 of the present row of pixel circuits at the same time. The first electrode plate 221 of the storage capacitor may be used as the gate of the third transistor T3.

In some examples, as shown in FIG. 10C, the second gate metal layer of the display region may at least include a first initial signal line INIT1, a second electrode plate 222 of the storage capacitor and a protection block 24. The protection block 24 may avoid interference of other signals to the data signal.

In some examples, as shown in FIG. 10D, the first source-drain metal layer of the display region may at least include a data line DL, a first power supply line VDD, and a plurality of connection electrodes (e.g. a first connection electrode 251, a second connection electrode 252, a third connection electrode 253, and a fourth connection electrode 254). The first connection electrode 251 may be electrically connected to the active layer T10 of the first transistor T1 and the first initial signal line INIT1. The second connection electrode 252 may be electrically connected to the active layer T20 of the second transistor T2 and the gate of the third transistor T3. The third connection electrode 253 may be electrically connected to the active layer T60 of the sixth transistor T6, and may be equivalent to the drain electrode of the sixth transistor T6. The fourth connection electrode 254 may be electrically connected to the first initial signal line INIT1 and the active layer T70 of the seventh transistor T7. The data line DL and the first power supply line VDD may both extend along the second direction Y. The data line DL may be electrically connected to the active layer of the fourth transistor T4. The first power supply line VDD may be electrically connected to the protection block 24, the second electrode plate 222 of the storage capacitor, and the active layer T50 of the fifth transistor T5.

In some examples, as shown in FIG. 9, the second source-drain metal layer of the display region may at least include a first transfer electrode 23, and a second connection segment 3225 of a second sub-line of the second detection line. The first transfer electrode 23 may be electrically connected to the third connection electrode 253. The second connection segment 3225 may be electrically connected to an active layer T40 of a data write transistor (i.e. the fourth transistor T4) of one pixel circuit. The second connection segment 3225 may serve as a source electrode of the data write transistor. One second sub-line 322 may be independently connected to a data write transistor T4 of one pixel circuit, so that interference to a normal display process may be reduced.

The following is an example of a crack detection method of the display panel of this example. In the following example, it is illustrated by taking that the first detection transistor and the second detection transistor are both P-type transistors as an example. However, the present embodiment is not limited thereto. In other examples, the first detection transistor and the second detection transistor may both be N-type transistors; or, the first detection transistor is a P-type transistor and the second detection transistor is an N-type transistor; or, the first detection transistor is an N-type transistor and the second detection transistor is a P-type transistor.

In some examples, as shown in FIG. 3, by controlling a voltage Vg1 of the first detection control signal transmitted by the first detection control lines 35a and 35b, a voltage Vg2 of the second detection control signal transmitted by the second detection control lines 37a and 37b, a voltage Vpcd1 of the first test signal transmitted by the first test signal transmission lines 36a and 36b, and a voltage Vpcd2 of the second test signal transmitted by the second test signal transmission lines 38a and 38b, and in combination with the display effect of the display region, it is possible to determine whether there is a crack in the peripheral region and accurately locate a position of the edge crack in the peripheral region.

In some examples, as shown in FIG. 3, the first detection transistors M1 and M1′ may be controlled to turn on through the first detection control signal, the second detection transistors M2 and M2′ may be controlled to turn off through the second detection control signal, the first test signal is provided to the first detection lines 31a and 31b through the first detection transistors M1 and M1′, and the transmission condition of the first test signal on the first detection lines 31a and 31b may be determined according to the display effect of the light emitting elements 62 connected to the first detection lines 31a and 31b in the display region, thereby locating crack positions of the third bezel region B3 and the fourth bezel region B4 of the peripheral region.

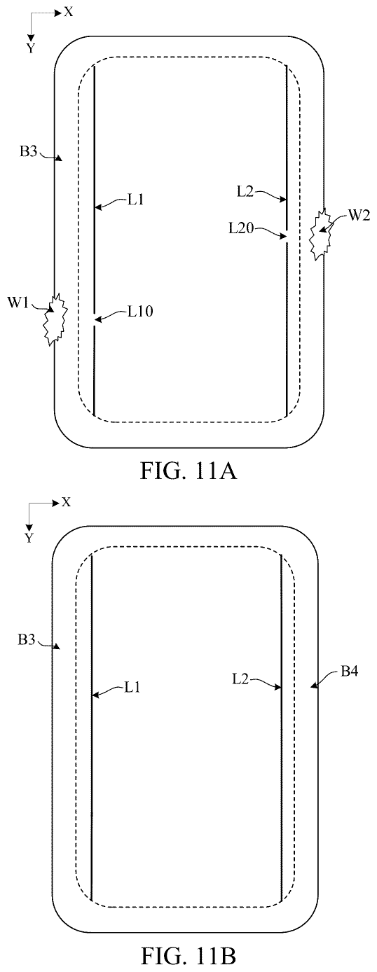

FIG. 11A and FIG. 11B are schematic diagrams of display patterns for crack detection of a third bezel region and a fourth bezel region according to at least one embodiment of the present disclosure. In this example, it is illustrated by taking that the first detection lines 31a and 31b are each connected with the light emitting elements 62 of a column of sub-pixel as an example. In some examples, in the crack detection process, when there are no cracks in the third bezel region B3 and the fourth bezel region B4, the first test signal transmitted by the first detection lines 31a and 31b may be normally provided to anodes of the connected light emitting elements 62, so that the connected light emitting elements 62 are normally displayed. In some examples, as shown in FIG. 11B, a first bright line L1 of the display region may indicate that there is no crack in the third bezel region B3, and the second bright line L2 may indicate that there is no crack in the fourth bezel region B4. The first bright line L1 and the second bright line L2 may be vertical penetrating bright lines.

In some examples, in the crack detection process, when there is a crack in the third bezel region B3 or the fourth bezel region B4, the first sub-line of the first detection line wound at the crack position cannot transmit the first test signal to the corresponding light emitting elements in the display region, the light emitting elements connected to the first sub-line at the crack position will not be lit, a vertical non-penetrating light line will appear in the display region, and the light line at a position corresponding to the crack will be disconnected. As shown in FIG. 11A, when a crack occurs at a first position W1 of the third bezel region B3, the first sub-line 312a wound at the first position W1 cannot transmit the first test signal to the corresponding light emitting element 62 in the display region, and the first bright line L1 of the display region may have a first fracture L10. A position of the crack which occurs at the first position W1 of the third bezel region B3 may be located according to the position of the first fracture L10. When a crack occurs at a second position W2 of the fourth bezel region B4, the second sub-line 312b wound at the second position W2 cannot transmit the first test signal to the corresponding light emitting element in the display region, and the second bright line L2 in the display region will have a second fracture L20. A position of the crack which occurs at the second position W2 of the fourth bezel region B4 may be located according to the position of the second fracture L20.

In some examples, the voltage Vg1 of the first detection control signal is set to be −7V, the voltage Vpcd1 of the first test signal is set to be 4.6 V, the first voltage signal Vdd is set to be 0V, the second voltage signal Vss is set to be 0V, the data voltage Vdata is set to be 0 to 5V, the voltage Vg2 of the second detection control signal is set to be 7V, and the voltage Vpcd2 of the second test signal is set to be 0V. At this time, the first detection transistors M1 and M1′ are turned on, and the second detection transistors M2 and M2′ are turned off. In the present example, the crack conditions of the third bezel region B3 and the fourth bezel region B4 may be determined according to the transmission condition of the first test signal tested by the first detection lines 31a and 31b. Since the first detection transistors M1 and M1′ are turned on, the voltage Vpcd1 of the first test signal may be transmitted to the first detection lines 31a and 31b, and the first main line 311a of the first detection line 31a and the first main line 311b of the first detection line 31b may transmit the first test signal to a plurality of first sub-lines 312a and 312b. Since the first sub-line 312a has a winding design within the third bezel region B3, when a crack occurs at an edge of the third bezel region B3, the first sub-line 312a corresponding to a crack position of the edge will be disconnected, and cannot transmit the first test signal to the corresponding light emitting elements, so that the corresponding light emitting elements will not emit light; and the first sub-line 312a at the non-crack position of the third bezel region B3 may normally transmit the first test signal to the corresponding light emitting elements, so that the corresponding light emitting elements normally emit light. Since the first sub-line 312b has a winding design within the fourth bezel region B4, when a crack occurs at an edge of the fourth bezel region B4, the first sub-line 312b corresponding to a crack position of the edge will be disconnected, and cannot transmit the first test signal to the corresponding light emitting elements, so that the corresponding light emitting elements will not emit light; and the first sub-line 312b at the non-crack position of the fourth bezel region B4 may normally transmit the first test signal to the corresponding light emitting elements, so that the corresponding light emitting elements normally emit light. In the present example, it is possible to accurately locate crack positions of the third bezel region B3 and the fourth bezel region B4 by using the first detection lines 31a and 31b.

In some examples, as shown in FIG. 3, the first detection transistors M1 and M1′ may be controlled to turn off through the first detection control signal, the second detection transistors M2 and M2′ may be controlled to turn on through the second detection control signal, the second test signal is provided to the second detection line 32 through the second detection transistors M2 and M2′, and the transmission condition of the second test signal on the second detection line 32 may be determined according to the display effect of the light emitting elements connected to the second detection line 32 in the display region, thereby determining whether there is a crack in the second bezel region and locating a crack position of the second bezel region of the peripheral region.

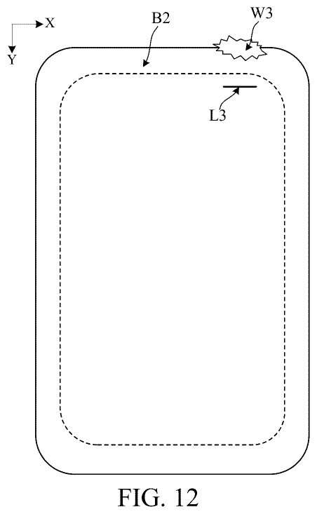

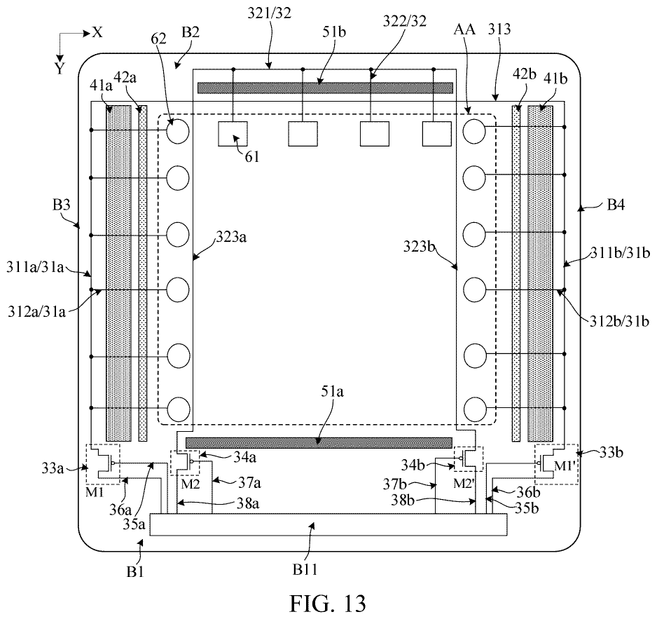

FIG. 12 is a schematic diagram of a display pattern of crack detection in a second bezel region according to at least one embodiment of the present disclosure. In this example, it is illustrated by taking pixel circuits of the remaining sub-pixels of a row of sub-pixels to which the second detection line 32 is connected except both ends of the row of sub-pixels as an example. In some examples, in a process of crack detection, when there is no crack in the second bezel region B2, the second test signal transmitted by the second detection line 32 may be normally provided to the connected pixel circuit, so that the light emitting elements to which the pixel circuit is connected do not emit light. For example, when a lateral penetrating dark line appears in the display region, it indicates that there is no crack in the second bezel region B2.

In some examples, in a process of crack detection, when there is a crack in the second bezel region B2, the second sub-line 322 of the second detection line 32 wound at the crack position cannot transmit the second test signal to the corresponding pixel circuit in the display region, the light emitting elements connected to the pixel circuit 61 connected to the second sub-line 322 at the crack position will be lit, a lateral non-penetrating dark line will appear in the display region, and a dark line at a position corresponding to the crack will break the displayed bright line. As shown in FIG. 12, when a crack occurs at a third position W3 of the second bezel region B2, the second sub-line 322 wound at the third position W3 cannot transmit the second test signal to the corresponding pixel circuit 61 in the display region, and the display region will display the third bright line L3. According to a position of the third bright line L3, it is possible to locate a position of the crack which occurs at the third position W3 of the second bezel region B2.

In some examples, the voltage Vg1 of the first detection control signal is set to be 7V, the voltage Vpcd1 of the first test signal is set to be 0V, the voltage Vg2 of the second detection control signal is set to be −7V, the voltage Vpcd2 of the second test signal is set to be 7V, the first voltage signal Vdd is set to be 4.6 V, and the second voltage signal Vss is set to be −2.4. At this time, the first detection transistors M1 and M1′ are turned off, and the second detection transistors M2 and M2′ are turned on. In the present example, the crack condition of the second bezel region B2 may be determined according to the transmission condition of the second test signal obtained by the second detection line 32. Since the second detection transistors M2 and M2′ are turned on, the voltage Vpcd2 of the second test signal may be transmitted to the second detection line 32, and the second main line 321 of the second detection line 32 may transmit the second test signal to a plurality of second sub-lines 322. Since the second sub-line 322 has a winding design within the second bezel region B2, when a crack occurs at an edge of the second bezel region B2, the second sub-line 322 corresponding to a crack position of the edge will be disconnected, and can not transmit the second test signal to the corresponding pixel circuit, so that the light emitting elements connected to the corresponding pixel circuit will be lit. The second sub-line 322 at a non-crack position of the second bezel region B2 may normally transmit the second test signal to the corresponding pixel circuit, so that the light emitting elements connected to the pixel circuit do not emit light. In this example, by using the second detection line 322, it is possible to determine whether there is a crack in the second bezel region B2 and accurately locate the crack position in the second bezel region B2.

In some examples, in a crack detection process, the voltage Vg1 of the first detection control signal and the voltage Vg2 of the second detection control signal may be set to be −7V, so that both the first detection transistor and the second detection transistor are turned on, and it is determined whether there are cracks in the third bezel region, the fourth bezel region and the second bezel region and the crack position can be located according to the display effects of two columns of sub-pixels and one row of sub-pixels.

In some examples, in a normal display process of the display region, the voltage Vg1 of the first detection control signal and the voltage Vg2 of the second detection control signal may be set to be 7V, so that both the first detection transistor and the second detection transistor are turned off, so as to avoid influence on the normal display process.

In other examples, the first bezel region of the display panel may be provided with a second detection line, and the second detection line may be provided in a manner similar to the second bezel region, which is not repeated in this embodiment.

In the display panel of the present example, the first detection line is arranged in the third bezel region and the fourth bezel region, and the second detection line is arranged in the second bezel region, the display effect of transmitting the first test signal by the first detection line and the display effect of transmitting the second test signal by the second detection line can be used to determine whether there is a crack in the bezel region, and the position of the crack can be accurately located according to the display effect, thereby improving the crack detection efficiency.

FIG. 13 is a schematic diagram of another display panel according to at least one embodiment of the present disclosure. In some examples, as shown in FIG. 13, the third bezel region B3 may be provided with a first detection line 31a, the fourth bezel region B4 may be provided with a first detection line 31b, and the second bezel region B2 may be provided with a second detection line 32.

In some examples, as shown in FIG. 13, the first detection line 31a may include a first main line 311a, and a plurality of first sub-lines 312a electrically connected to the first main line 311a. The first main line 311a may be located on a side of the gate drive circuit 41a away from the display region AA, and the plurality of first sub-lines 312a may be located on a side of the first main line 311a close to the display region AA. The plurality of first sub-lines 312a may be sequentially arranged along the second direction Y and extend to the display region AA along the first direction X, and are electrically connected to the plurality of light emitting elements 62 in the display region AA in one-to-one correspondence. When the first sub-lines 312a pass through the gate drive circuit 41a and the bezel initial signal line 42a, a first cross-line located in the bottom shielding metal layer may be used to achieve jumping wire, so as to avoid interference and prevent short circuit between different signals.

In some examples, as shown in FIG. 13, the first detection line 31b may include a first main line 311b, and a plurality of first sub-lines 312b electrically connected to the first main line 311b. The first main line 311b may be located on a side of the gate drive circuit 41b away from the display region AA, and the plurality of first sub-lines 312b may be located on a side of the first main line 311b close to the display region AA. The plurality of first sub-lines 312b may be sequentially arranged along the second direction Y and extend to the display region AA along the first direction X, and are electrically connected to the plurality of light emitting elements 62 within the display region AA in one-to-one correspondence. When the first sub-lines 312b pass through the gate drive circuit 41b and the bezel initial signal line 42b, a first cross-line located in the bottom shielding metal layer may be used to achieve jumping wire, so as to avoid interference and prevent short circuit between different signals.

In some examples, as shown in FIG. 13, the second detection line 32 may include a second main line 321, and a plurality of second sub-lines 322 electrically connected to the second main line 321. The second main line 321 may be located on a side of the first power supply bezel line 51b away from the display region AA, and the plurality of second sub-lines 322 may be located on a side of the second main line 321 close to the display region AA. The plurality of second sub-lines 322 may be sequentially arranged along the first direction X and extend to the display region AA along the second direction Y, and are electrically connected to the plurality of pixel circuits 61 within the display region AA in one-to-one correspondence. When the second sub-lines 321 pass through the first power supply bezel line 51b, a third cross-line located in the bottom shielding metal layer may be used to achieve jumping wire, so as to avoid interference and prevent short circuit between different signals.

In some examples, in a crack detection process, when there is a crack in the third bezel region B3, and the first main line 311a and the first sub-line 312a passing through the crack position cannot continue to transmit the first test signal, the first test signals will not be received both at the crack position and the light emitting elements 62 connected to the first sub-line 312a on a side of the crack position away from the first bezel region B1, and the light emitting elements 62 cannot be lit. The display region AA will display a local bright line, and an edge of the third bezel region B3 corresponding to a position where there is no bright line will have a crack. When there is no crack in the third bezel region B3, the display region AA may display the first bright line L1 as shown in FIG. 11B. In the same way, it may be determined whether there is a crack in the fourth bezel region B4 and the position of the crack.

In some examples, in a crack detection process, when there is a crack in the second bezel region B2, and the second main line 321 and the second sub-line 322 passing through the crack position cannot continue to transmit the second test signal, the light emitting elements of the connected pixel circuit at a position of the second sub-line 322 which cannot transmit the second test signal will be lit, and a bright line will be displayed correspondingly in the display region AA. The crack position of the second bezel region B2 may be determined according to a position of the bright line of the display region AA.

Rest of description of the display panel of the example may be referred to description of the aforementioned embodiments, and thus will not be repeated here.

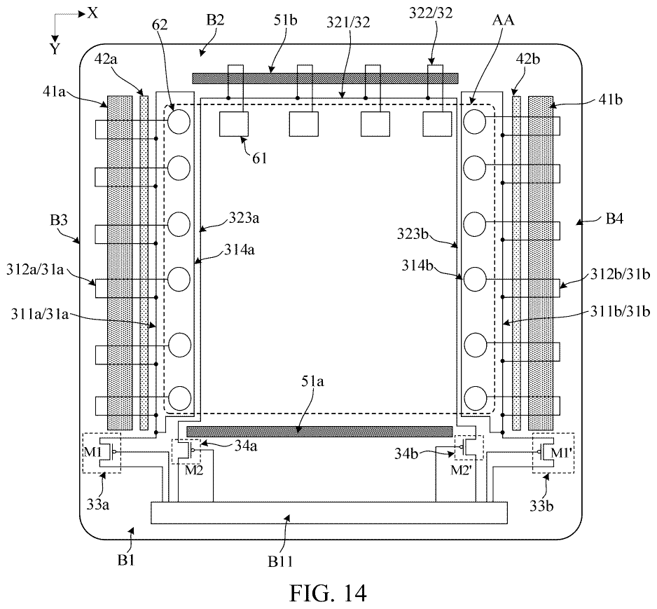

FIG. 14 is a schematic diagram of another display panel according to at least one embodiment of the present disclosure. In some examples, as shown in FIG. 14, the third bezel region B3 may be provided with a first detection line 31a, and the first detection line 31a may be electrically connected to a third connection line 314a, which may be located in the display region. The fourth bezel region B4 may be provided with a first detection line 31b, which may be electrically connected to a third connection line 314b. The third connection line 314b may be located in the display region. In some examples, the third connection line 314a may be located on a side of the second connection line 323a close to the third bezel region B3, and the third connection line 314b may be located on a side of the second connection line 323b close to the fourth bezel region B4. The first detection lines 31a and 31b of the present example are not directly connected, but each achieves a connection loop with the first detection control unit through a third connection line. In the present example, it may be avoided from occupying the wiring space of the second bezel region B2.

Rest of description of the display panel of the example may be referred to description of the aforementioned embodiments, and thus will not be repeated here.

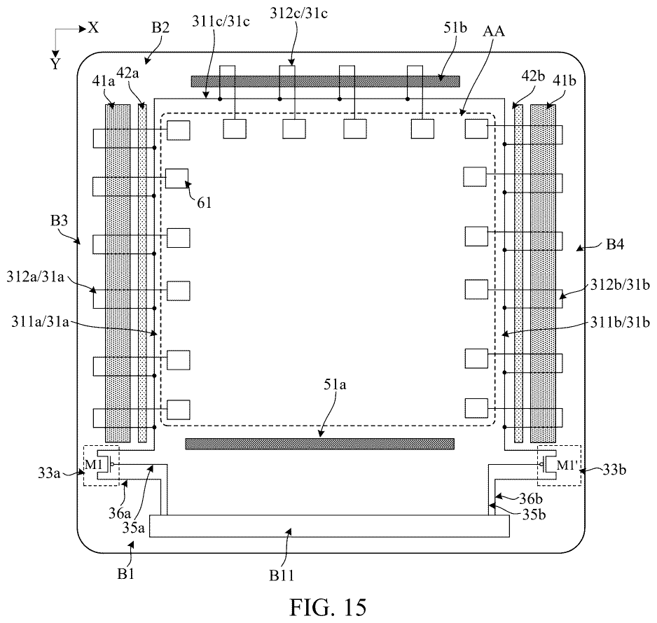

FIG. 15 is a schematic diagram of another display panel according to at least one embodiment of the present disclosure. In some examples, as shown in FIG. 15, the third bezel region B3 may be provided with a first detection line 31a, the fourth bezel region B4 may be provided with a first detection line 31b, and the second bezel region B2 may be provided with a first detection line 31c. Both ends of the first detection line 31c may be electrically connected to the first detection line 31a and the first detection line 31b, respectively. The first detection line 31a may be electrically connected to the first detection control unit 33a, and the first detection line 31b may be electrically connected to the first detection control unit 33b.

In some examples, as shown in FIG. 15, the first detection line 31a may include a first main line 311a and a plurality of first sub-lines 312a The first main line 311a may be located on a side of the gate drive circuit 41a close to the display region AA, and partial line segments (e.g. the aforementioned first line segment) of each first sub-line 312a may be located on a side of the gate drive circuit 41a away from the display region AA. The plurality of first sub-lines 312a may be sequentially arranged along the second direction Y and extend to the display region AA, and are electrically connected to a plurality of pixel circuits 61 within the display region AA in one-to-one correspondence. When the first sub-lines 312a pass through the gate drive circuit 41a and the bezel initial signal line 42a, a first cross-line and a second cross-line located in the bottom shielding metal layer may be used to achieve jumping wire, so as to avoid interference and prevent short circuit between different signals.

In some examples, as shown in FIG. 15, the first detection line 31b may include a first main line 311b, and a plurality of first sub-lines 312b electrically connected to the first main line 311b. The first main line 311b may be located on a side of the gate drive circuit 41b close to the display region AA, and partial line segments of each first sub-line 312b may be located on a side of the gate drive circuit 41b away from the display region AA. The plurality of first sub-lines 312b may be sequentially arranged along the second direction Y and extend to the display region AA, and are electrically connected to a plurality of pixel circuits 61 within the display region AA in one-to-one correspondence. When the first sub-lines 312b pass through the gate drive circuit 41b and the bezel initial signal line 42b, a first cross-line and a second cross-line located in the bottom shielding metal layer may be used to achieve jumping wire, so as to avoid interference and prevent short circuit between different signals.

In some examples, as shown in FIG. 15, the first detection line 31c may include a first main line 311c, and a plurality of first sub-lines 312c electrically connected to the first main line 311c. The first main line 311c may be located on a side of the first power supply bezel line 51b close to the display region AA. The plurality of first sub-lines 312c may be sequentially arranged along the second direction Y and extend to the display region AA, and are electrically connected to a plurality of pixel circuits 61 within the display region AA in one-to-one correspondence. When the first sub-lines 312c pass through the first power supply bezel line 51b, a cross-line located in the bottom shielding metal layer may be used to achieve jumping wire, so as to avoid interference and prevent short circuit between different signals.

In some examples, in a crack detection process, it is possible to determine whether there are cracks in the third bezel region, the fourth bezel region, and the second bezel region and the locations of the cracks according to the display conditions of two columns of sub-pixels and one row of sub-pixels connected to the first detection lines 31a, 31b, and 31c. In this example, the crack location may be located according to a position of a bright line in the display region in a crack detection process. However, the present embodiment is not limited thereto. In other examples, the first main line of the first detection line may be located on a side of the plurality of first sub-lines away from the display region.

Rest of description of the display panel of the example may be referred to description of the aforementioned embodiments, and thus will not be repeated here.

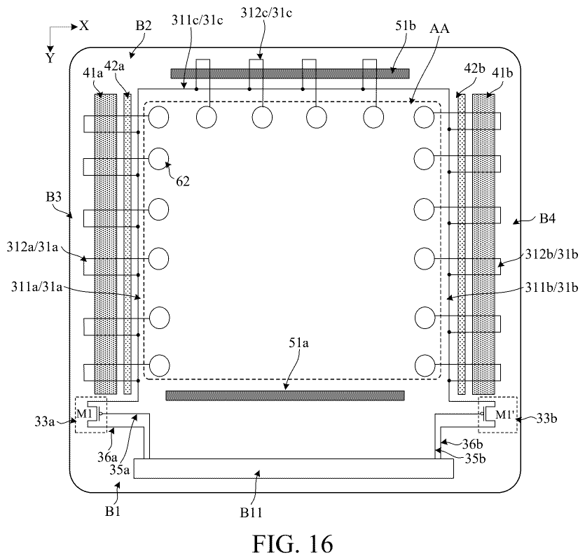

FIG. 16 is a schematic diagram of another display panel according to at least one embodiment of the present disclosure. In some examples, as shown in FIG. 16, the third bezel region B3 may be provided with a first detection line 31a, the fourth bezel region B4 may be provided with a first detection line 31b, and the second bezel region B2 may be provided with a first detection line 31c. Both ends of the first detection line 31c may be electrically connected to the first detection line 31a and the first detection line 31b, respectively. The first detection line 31a may be electrically connected to the first detection control unit 33a, and the first detection line 31b may be electrically connected to the first detection control unit 33b. The first detection lines 31a 31b and 31c are electrically connected to anodes of the light emitting elements 62 of a plurality of sub-pixels of the display region, respectively. In this example, the crack location may be located according to a position of a dark line in the display region in a crack detection process. However, the present embodiment is not limited thereto. In other examples, the first main line of the first detection line may be located on a side of the plurality of first sub-lines away from the display region.

Rest of description of the display panel of the example may be referred to description of the aforementioned embodiments, and thus will not be repeated here.

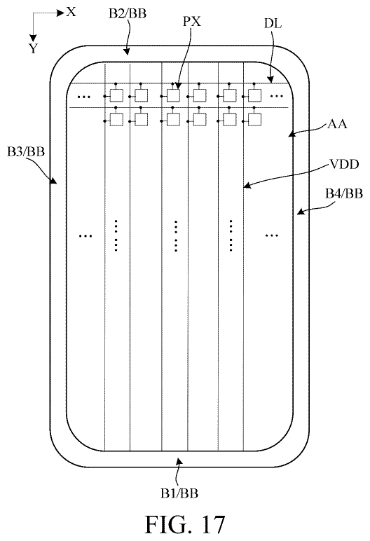

FIG. 17 is a planar schematic diagram of another display panel according to at least one embodiment of the present disclosure. In some examples, as shown in FIG. 17, the display region AA may include a plurality of sub-pixels PX, a plurality of data lines DL extending along the first direction X, and a plurality of first power supply lines VDD extending along the second direction Y. The plurality of data lines DL may be sequentially arranged along the second direction Y, and the plurality of first power supply lines VDD may be sequentially arranged along the first direction X. Each data line DL may be electrically connected to pixel circuits of a plurality of sub-pixels arranged along the first direction X, and is configured to provide data signals to the plurality of pixel circuits. Each first power supply line VDD may be electrically connected to a pixel circuit of a plurality of sub-pixels arranged along the second direction Y, and is configured to provide first voltage signals to the plurality of sub-pixels. In some examples, the data line DL and the first power supply line VDD may be located in different films, so as to avoid mutual interference between them. For example, the data line DL may be located in the first source-drain metal layer, and the first power supply line VDD may be located in the second source-drain metal layer; or the data line DL may be located in the second source-drain metal layer, and the first power supply line VDD may be located in the first source-drain metal layer.

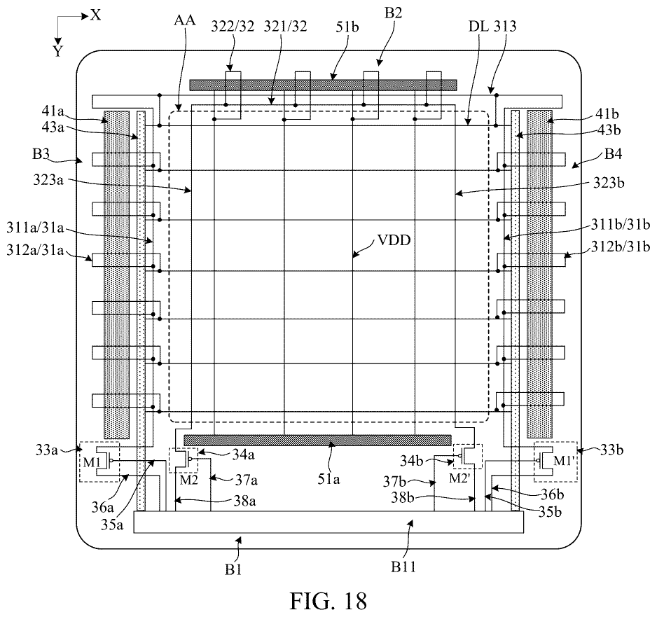

FIG. 18 is a schematic diagram of another display panel according to at least one embodiment of the present disclosure. In some examples, as shown in FIG. 18, a plurality of data lines DL of the display region AA extend along the first direction X, and a plurality of first power supply lines VDD extend along the second direction Y. The third bezel region B3 may be provided with a data supply bus (or data supply circuit) 43a and a gate drive circuit 41a. The data supply bus 43a may be located on a side of the gate drive circuit 41a close to the display region AA. The fourth bezel region B4 may be provided with a data supply bus 43b and a gate drive circuit 41b. The data supply bus 43b may be located on a side of the gate drive circuit 41b close to the display region AA. A plurality of data lines DL of the display region AA may be electrically connected to the data supply buses 43a and 43b. The data supply buses 43a and 43b may be electrically connected to a plurality of data pins within the signal access region B11. An integrated circuit provided in the signal access region B11 may be configured to provide data signals through the plurality of data pins.

In some examples, as shown in FIG. 18, the third bezel region B3 may be provided with a first detection line 31a. The first detection line 31a may include a first main line 311a and a plurality of first sub-lines 312a. The first main line 311a may be located on a side of the data supply bus 43a close to the display region AA. The plurality of first sub-lines 312a may be arranged sequentially along the second direction Y, and are electrically connected to the first main line 311a. For example, the first sub-line 312a may extend along the first direction X to a side of the first main line 311a away from the display region AA until it extends to a side of the gate drive circuit 41a away from the display region AA, then the first sub-line 312a may be wound to extend along the first direction X to a side close to the display region AA and finally it extends to be electrically connected to one data line DL. The plurality of first sub-lines 312a may be electrically connected with the plurality of data lines DL in one-to-one correspondence. A connection position between the first sub-line 312a and the data line DL may be located on a side of the first main line 311a close to the display region AA, or may be located within the display region AA. The present embodiment is not limited thereto. When the first sub-lines 312a pass through the gate drive circuit 41a and the data supply bus 43a, a first cross-line and a second cross-line located in the bottom shielding metal layer may be used to achieve jumping wire, so as to avoid interference and prevent short circuit between different signals.

In some examples, as shown in FIG. 18, the fourth bezel region B4 may be provided with a first detection line 31b. The first detection line 31b may include a first main line 311b and a plurality of first sub-lines 312b. The first main line 311b may be located on a side of the data supply bus 43b close to the display region AA. The plurality of first sub-lines 312b may be arranged sequentially along the second direction Y, and are electrically connected to the first main line 311b. For example, the first sub-line 312b may extend along the first direction X to a side of the first main line 311b away from the display region AA until it extends to a side of the gate drive circuit 41b away from the display region AA, then the first sub-line 312b may be wound to extend along the first direction X to a side close to the display region AA and finally it extends to be electrically connected to one data line DL. The plurality of first sub-lines 312b may be electrically connected with the plurality of data lines DL in one-to-one correspondence. A connection position between the first sub-line 312b and the data line DL may be located on a side of the first main line 311b close to the display region AA, or may be located within the display region AA. The present embodiment is not limited thereto. When the first sub-lines 312b pass through the gate drive circuit 41b and the data supply bus 43b, a first cross-line and a second cross-line located in the bottom shielding metal layer may be used to achieve jumping wire, so as to avoid interference and prevent short circuit between different signals.

In some examples, as shown in FIG. 18, the second bezel region B2 may be provided with a first power supply bezel line 51b, and a second detection line 32. The second detection line 32 may be electrically connected to the second detection control unit 34a through the second connection line 323a located in the display region AA, and is electrically connected to the second detection control unit 34b through the second connection line 323b located in the display region AA. The second detection line 32 may include a second main line 321 and a plurality of second sub-lines 322. The second main line 321 may be located on a side of the first power supply bezel line 51b close to the display region AA. Partial line segments (e.g. the aforementioned third line segment) of each second sub-line 322 may be located on a side of the first power supply bezel line 51b away from the display region AA. After being connected to the second main line 321, each second sub-line 322 may extend along the second direction Y to a side away from the display region AA until passing through the first power supply bezel line 51b, then is wound and extend along the second direction Y to a side close to the display region AA, and finally extend to be electrically connected to one first power supply line VDD within the display region AA. The plurality of second sub-lines 322 may be electrically connected with the plurality of first power supply lines VDD in one-to-one correspondence. When the second sub-lines 322 pass through the first power supply bezel line 51b, a third cross-line and a fourth cross-line located in the bottom shielding metal layer may be used to achieve jumping wire, so as to avoid interference and prevent short circuit between different signals.

In some examples, the number of data lines to which the first detection line 31a is connected and the number of data lines to which the first detection line 31b is connected may be the same. The plurality of data lines to which the first detection line 31a is connected and the plurality data lines to which the first detection line 31b is connected may be the same. However, the present embodiment is not limited thereto. The plurality of data lines to which the first detection line 31a is connected may be different from the plurality of data lines to which the first detection line 31b is connected, so as to better distinguish crack positions of the third bezel region B3 and the fourth bezel region B4. In the present example, the number of data lines to which the first detection line 31a is connected and the number of first power supply lines to which the second detection line 31b is connected are not limited.

The following is an example of a crack detection method for the display panel of this example. In the following example, it is illustrated by taking that the first detection transistor and the second detection transistor are both P-type transistors as an example.

In some examples, as shown in FIG. 18, in a crack detection process, when there are no cracks in the third bezel region B3 and the fourth bezel region B4, the first test signals transmitted by the first detection lines 31a and 31b may be normally provided to the connected data line DL, so that the sub-pixels connected by the data line DL do not emit light, and the display region AA may display a plurality of dark lines. When there is a crack in the third bezel region B3 or the fourth bezel region B4, the first sub-line of the first detection line wound at the crack position cannot transmit the first test signal to the corresponding data line, so that the sub-pixels connected to the data line corresponding to the crack position will be lit, and the display region AA will display the corresponding bright line. In this way, it is possible to determine whether there are cracks in the third bezel region B3 and the fourth bezel region B4 and crack positions of the third bezel region B3 and the fourth bezel region B4 according to a position of a lateral bright line of the display region.

In some examples, the voltage Vg1 of the first detection control signal is set to be −7V, the voltage Vpcd1 of the first test signal is set to be 7V, the voltage Vg2 of the second detection control signal is set to be 7V, the voltage Vpcd2 of the second test signal is set to be 0V, and the data voltage Vdata is set to be 7V. At this time, the first detection transistors M1 and M1′ are turned on, and the second detection transistors M2 and M2′ are turned off. When there are no cracks in the third bezel region B3 and the fourth bezel region B4, the display regions all display dark lines; and when there is a crack in the third bezel region B3 or the fourth bezel region B4, the display region will display a bright line at a corresponding position. In this way, crack positions of the third bezel region B3 and the fourth bezel region B4 may be located according to positions of bright lines of the display region.

In some examples, as shown in FIG. 18, in a crack detection process, when there is no crack in the second bezel region B2, the second test signal transmitted by the second detection line 32 may be normally provided to the connected first power supply line VDD, for example, so that the sub-pixels connected to the first power supply line VDD may be normally displayed. When there is a crack in the second bezel region B2, the second test signal transmitted by the second detection line 32 cannot be provided to the connected first power supply line VDD, for example, so that the sub-pixels to which the first power supply line VDD is connected cannot be displayed normally. In this way, a crack position of the second bezel region B2 may be located according to a position of a dark line of the display region. However, the present embodiment is not limited thereto. In other examples, when there is no crack in the second bezel region B2, the second test signal may be used to make the sub-pixels to which the first power supply line VDD is connected not displayed, and when there is a crack in the second bezel region B2, the sub-pixels to which the first power supply line VDD is connected are made to be displayed, thereby locating a crack position according to a position of a bright line of the display region.

In some examples, the voltage Vg1 of the first detection control signal is set to be 7V, the voltage Vpcd1 of the first test signal is set to be 0V, the voltage Vg2 of the second detection control signal is set to be −7V, the voltage Vpcd2 of the second test signal is set to be 4.6V, and the first voltage signal Vdd and the second voltage signal Vss are both set to be 0V. At this time, the first detection transistors M1 and M1′ are turned off, and the second detection transistors M2 and M2′ are turned on. When there is no crack in the second bezel region B2, the display region may display a bright line; and when there is a crack in the second bezel region B2, the display region may display a dark line at a corresponding position. In this way, a crack position of the second bezel region B2 may be located according to a position of a dark line of the display region.

In some examples, in a crack detection process, the voltage Vg1 of the first detection control signal and the voltage Vg2 of the second detection control signal may be set to be −7V, so that both the first detection transistor and the second detection transistor are turned on, and it is determined whether there are cracks in the third bezel region, the fourth bezel region and the second bezel region and where the crack position is located according to the display effects of different rows and different columns of sub-pixels.

In the display panel of the present example, the first detection line is arranged in the third bezel region and the fourth bezel region, and the second detection line is arranged in the second bezel region, the display effect of transmitting the first test signal by the first detection line to the data line and the display effect of transmitting the second test signal by the second detection line to the first power supply line may be used to determine whether there is a crack in the bezel region, and the position of the crack can be accurately located according to the display effect, thereby improving the crack detection efficiency.

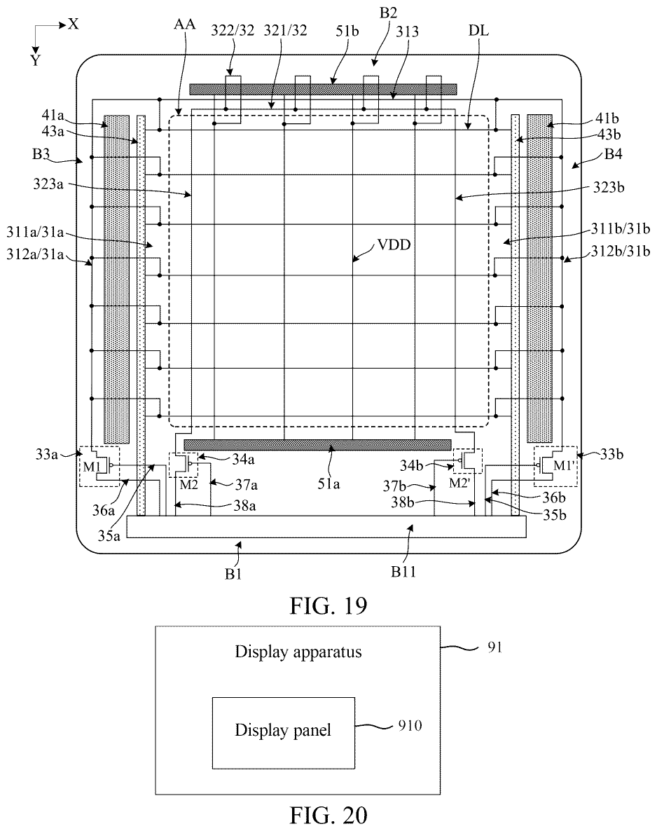

FIG. 19 is a schematic diagram of another display panel according to at least one embodiment of the present disclosure. In some examples, as shown in FIG. 19, the third bezel region B3 may be provided with a first detection line 31a, the fourth bezel region B4 may be provided with a first detection line 31b, and the second bezel region B2 may be provided with a second detection line 32.

In some examples, as shown in FIG. 19, the first detection line 31a may include a first main line 311a, and a plurality of first sub-lines 312a electrically connected to the first main line 311a. The first main line 311a may be located on a side of the gate drive circuit 41a away from the display region AA, and the plurality of first sub-lines 312a may be located on a side of the first main line 311a close to the display region AA. The plurality of first sub-lines 312a may be sequentially arranged along the second direction Y and extend to the display region AA along the first direction X, and are electrically connected to the plurality of data lines DL in the display region AA in one-to-one correspondence. When the first sub-lines 312a pass through the gate drive circuit 41a and the data supply bus 43a, a first cross-line located in the bottom shielding metal layer may be used to achieve jumping wire, so as to avoid interference and prevent short circuit between different signals.

In some examples, as shown in FIG. 19, the first detection line 31b may include a first main line 311b, and a plurality of first sub-lines 312b electrically connected to the first main line 311b. The first main line 311b may be located on a side of the gate drive circuit 41b away from the display region AA, and the plurality of first sub-lines 312b may be located on a side of the first main line 311b close to the display region AA. The plurality of first sub-lines 312b may be sequentially arranged along the second direction Y and extend to the display region AA along the first direction X, and are electrically connected to the plurality of data lines DL in the display region AA in one-to-one correspondence. When the first sub-lines 312b pass through the gate drive circuit 41b and the data supply bus 43b, a first cross-line located in the bottom shielding metal layer may be used to achieve jumping wire, so as to avoid interference and prevent short circuit between different signals.

In some examples, as shown in FIG. 19, the second detection line 32 may include a second main line 321, and a plurality of second sub-lines 322 electrically connected to the second main line 321. The second main line 321 may be located on a side of the first power supply bezel line 51b away from the display region AA, and the plurality of second sub-lines 322 may be located on a side of the second main line 321 close to the display region AA. The plurality of second sub-lines 322 may be sequentially arranged along the first direction X and extend to the display region AA along the second direction Y, and are electrically connected to the plurality of first power supply lines VDD within the display region AA in one-to-one correspondence. When the second sub-lines 321 pass through the first power supply bezel line 51b, a third cross-line located in the bottom shielding metal layer may be used to achieve jumping wire, so as to avoid interference and prevent short circuit between different signals.

In some examples, in a crack detection process, when there is a crack in the third bezel region B3, and the first main line 311a and the first sub-line 312a passing through the crack position cannot continue to transmit the first test signal, the first test signals will not be received both at the crack position and the data line DL connected to the first sub-line 312a on a side of the crack position away from the first bezel region B1, and the sub-pixel connected to the data line DL will be lit. Thus there is a crack at an edge of the third bezel region B3 corresponding to a position of the bright line in the display region. When there is no crack in the third bezel region B3, the display region may display a dark line. In the same way, it may be determined whether there is a crack in the fourth bezel region B4 and the position of the crack.

In some examples, in a crack detection process, when there is a crack in the second bezel region B2, and the second main line 321 and the second sub-line 322 passing through the crack position cannot continue to transmit the second test signal, the light emitting elements connected to the connected first power supply line at a position of the second sub-line 322 which cannot transmit the second test signal cannot be lit, and a dark line will be displayed correspondingly in the display region AA. The crack position of the second bezel region B2 may be determined according to a position of the dark line of the display region AA.

Rest of description of the display panel of the example may be referred to description of the aforementioned embodiments, and thus will not be repeated here.

The present embodiment further provides a crack detection method, which is applied to the display panel as described above, and the crack detection method includes: providing a first test signal to a first detection line through a first detection control unit, and determining whether there is a crack in a peripheral region and a position where the crack is located according to a light emitting state of a plurality of sub-pixels electrically connected to the first detection line.

In some exemplary implementations, the crack detection method of the present example further includes: providing a second test signal to a second detection line through a second detection control unit, and determining whether there is a crack in the peripheral region and a position where the crack is located according to a light emitting state of a plurality of sub-pixels electrically connected to the second detection line.

The description of the crack detection method of the present example may be referred to description of the aforementioned embodiments, and thus will not be repeated here.

The present embodiment further provides a display panel, including a base substrate, a plurality of sub-pixels, at least one first detection line, and at least one first detection control unit. The base substrate includes a display region and a peripheral region located at a periphery of the display region. The plurality of sub-pixels is located in the display region. At least one first detection line and at least one first detection control unit are located at the peripheral region, the at least one first detection control unit is electrically connected with the at least one first detection line and is configured to provide a first test signal to the at least one first detection line. The at least one first detection line is electrically connected with the plurality of sub-pixels of the display region. The at least one first detection line includes a first main line, and a plurality of first sub-lines electrically connected with the first main line, the plurality of first sub-lines extend to the display region, and each first sub-line is electrically connected with at least one sub-pixel of the display region. A portion of line segments of at least one first sub-line of the plurality of first sub-lines is located on a side of the first main line away from the display region. For example, a portion of line segments of each of the plurality of first sub-lines (e.g. the first line segment of the aforementioned embodiment) may be located on a side of the first main line away from the display region.

In some exemplary implementations, the peripheral region may be provided with gate drive circuit. The first main line may be located on a side of the gate drive circuit close to the display region, and a portion of the line segments of each first sub-line may be located on a side of the gate drive circuit away from the display region.

In some exemplary implementations, the display panel may further include a second detection line and at least one second detection control unit which are located at the peripheral region; and the at least one second detection control unit is electrically connected to the second detection line, and is configured to provide a second test signal to the second detection line. The second detection line is electrically connected with the plurality of sub-pixels of the display region. A connection mode between the second detection line and the plurality of sub-pixels of the display region is different from a connection mode between the first detection line and the plurality of sub-pixels of the display region. In some examples, as shown in FIG. 3, the first detection line may be electrically connected to anodes of light emitting elements of a plurality of sub-pixels, and the second detection line may be electrically connected to source electrodes of data write transistors of pixel circuits of a plurality of sub-pixels. In other examples, as shown in FIG. 18, the first detection line may be electrically connected to a plurality of data lines, and the second detection line may be electrically connected to a plurality of first power supply lines.

In some exemplary implementations, the second detection line may include a second main line and a plurality of second sub-lines electrically connected to the second main line; each second sub-line is electrically connected with at least one sub-pixel of the display region, and the plurality of second sub-lines are sequentially arranged along an extension direction of the second main line. The extension direction of the second main line intersects with the extension direction of the first main line of the first detection line.

Description of the display panel of the example may be referred to description of the aforementioned embodiments, and thus will not be repeated here.

FIG. 20 is a schematic diagram of a display device according to at least one embodiment of the present disclosure. As shown in FIG. 20, an embodiment provides a display apparatus, which includes a display panel 91 and a sensor 92 located on a light exit side of a light emitting structure layer away from the display panel 91. The sensor 92 may be located on a side of a non-display surface of the display panel 91. An orthographic projection of the sensor 92 on the display panel 91 may be overlapped with a first display region A1.

In some exemplary implementations, the display panel 91 may be a flexible OLED display panel, a QLED display panel, a Micro-LED display panel, or a Mini-LED display panel. The display apparatus may be a product having an image (including a still image or a moving image, wherein the moving image may be a video) display function. For example, the display apparatus may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device including a micro-display, or an AR device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display panel, comprising:
a base substrate, comprising a display region and a peripheral region located at a periphery of the display region;
a plurality of sub-pixels and a plurality of data lines located in the display region, wherein the plurality of sub-pixels are electrically connected with the plurality of data lines, at least one sub-pixel of the plurality of sub-pixels comprises a pixel circuit and a light emitting element, and the pixel circuit is electrically connected with the light emitting element and is configured to drive the light emitting element to emit light; and
at least one first detection line and at least one first detection control unit, located at the peripheral region, the at least one first detection control unit is electrically connected with the at least one first detection line and is configured to provide a first test signal to the at least one first detection line, wherein
the at least one first detection line is electrically connected with the plurality of sub-pixels of the display region in any of the following ways:
the at least one first detection line is electrically connected with anodes of light emitting elements of the plurality of sub-pixels of the display region;
the at least one first detection line is electrically connected with source electrodes of data write transistors of pixel circuits of the plurality of sub-pixels of the display region; and
the at least one first detection line is electrically connected with the plurality of data lines of the display region, at least one data line of the plurality of data lines is electrically connected with the plurality of sub-pixels arranged along a first direction, and the at least one first detection line is located at least in peripheral regions on opposite sides of the display region along the first direction.

2. The display panel according to claim 1, wherein the at least one first detection line comprises: a first main line and a plurality of first sub-lines electrically connected to the first main line, and each first sub-line is electrically connected to at least one sub-pixel of the display region; and the plurality of first sub-lines are arranged sequentially along an extension direction of the first main line.

3. The display panel according to claim 2, wherein the peripheral region is further provided with a gate drive circuit; and
the first main line is located on a side of the gate drive circuit close to the display region, and a portion of line segments of each first sub-line is located on a side of the gate drive circuit away from the display region.

4. The display panel according to claim 2, wherein the peripheral region is further provided with a gate drive circuit; and
the first main line is located on a side of the gate drive circuit away from the display region, and the plurality of first sub-lines are located on a side of the first main line close to the display region.

5. The display panel according to claim 2, wherein the plurality of sub-pixels electrically connected to the plurality of first sub-lines of the first detection line comprises a plurality of sub-pixels within the display region closest to the first main line and arranged along the extension direction of the first main line.

6. The display panel according to claim 3, wherein each first sub-line at least comprises a first line segment, a second line segment, and a first cross-line; wherein both ends of the first cross-line are electrically connected to the first line segment and the second line segment, respectively, the first line segment is located on a side of the gate drive circuit away from the display region, and the second line segment is located on a side of the gate drive circuit close to the display region; an orthographic projection of the first cross-line on the base substrate is at least partially overlapped with an orthographic projection of the gate drive circuit on the base substrate; and the first cross-line line is located on a side of the first line segment and the second line segment close to the base substrate.

7. The display panel according to claim 6, wherein in a direction perpendicular to the display panel, the display panel at least comprises a base substrate, and a bottom shielding metal layer, and a semiconductor layer, a first gate metal layer, a second gate metal layer, a first source-drain metal layer and a second source-drain metal layer which are arranged on the base substrate; and
the first cross-line is located in the bottom shielding metal layer, and the first line segment and the second line segment are located in the first gate metal layer.

8. The display panel according to claim 2, wherein the at least one first detection control unit comprises a first detection transistor, wherein a gate electrode of the first detection transistor is electrically connected with a first detection control line, a first electrode of the first detection transistor is electrically connected with a first test signal transmission line, and a second electrode of the first detection transistor is electrically connected with the first detection line.

9. The display panel according to claim 2, further comprising: a second detection line and at least one second detection control unit which are located at the peripheral region; and the at least one second detection control unit is electrically connected with the second detection line and is configured to provide a second test signal to the second detection line;
the second detection line is electrically connected with the plurality of sub-pixels of the display region; and
a connection mode between the second detection line and the plurality of sub-pixels of the display region is different from a connection mode between the first detection line and the plurality of sub-pixels of the display region.

10. The display panel according to claim 9, wherein the second detection line comprises a second main line and a plurality of second sub-lines electrically connected to the second main line; each second sub-line is electrically connected with at least one sub-pixel of the display region, and the plurality of second sub-lines are arranged sequentially along an extension direction of the second main line; and
the extension direction of the second main line is intersected with the extension direction of the first main line of the first detection line.

11. The display panel according to claim 10, wherein the plurality of first sub-lines of the at least one first detection line are electrically connected to the anodes of the light emitting elements of the plurality of sub-pixels of the display region in one-to-one correspondence; and
the plurality of second sub-lines of the second detection line are electrically connected with the source electrodes of the data write transistors of the pixel circuits of the plurality of sub-pixels of the display region in one-to-one correspondence.

12. The display panel according to claim 10, wherein the plurality of first sub-lines of the at least one first detection line are electrically connected to the plurality of data lines of the display region in one-to-one correspondence; and the plurality of data lines are extended along the first direction; and
the plurality of second sub-lines of the second detection line are electrically connected with a plurality of first power supply lines of the display region in one-to-one correspondence, the plurality of first power supply lines are extended along a second direction, and the second direction is intersected with the first direction.

13. The display panel according to claim 10, wherein the peripheral region is further provided with a first power supply bezel line; and
the second main line is located on a side of the first power supply bezel line close to the display region, and a portion of each second sub-line is located on a side of the first power supply bezel line away from the display region.

14. The display panel according to claim 10, wherein the peripheral region is further provided with a first power supply bezel line; and
the second main line is located on a side of the first power supply bezel line away from the display region, and the plurality of second sub-lines are located on a side of the second main line close to the display region.

15. The display panel according to claim 10, wherein the plurality of sub-pixels electrically connected to the plurality of second sub-lines of the second detection line comprises a plurality of sub-pixels within the display region closest to the second main line and arranged along the extension direction of the second main line.

16. The display panel according to claim 13, wherein each second sub-line at least comprises a third line segment, a fourth line segment, and a third cross-line; wherein both ends of the third cross-line are electrically connected to the third line segment and the fourth line segment, respectively, the third line segment is located on a side of the first power supply bezel line away from the display region, and the fourth line segment is located on a side of the first power supply bezel line close to the display region; an orthographic projection of the third cross-line on the base substrate is at least partially overlapped with an orthographic projection of the first power supply bezel line on the base substrate; and the third cross-line is located on a side of the third line segment and the fourth line segment close to the base substrate.

17. The display panel according to claim 16, wherein in a direction perpendicular to the display panel, the display panel at least comprises a base substrate, and a bottom shielding metal layer, a semiconductor layer, a first gate metal layer, a second gate metal layer, a first source-drain metal layer, and a second source-drain metal layer, which are arrange on the base substrate; and
the third cross-line is located in the bottom shielding metal layer, and the third line segment and the fourth line segment are located in the first gate metal layer.

18. The display panel according to claim 9, wherein the second detection control unit comprises a second detection transistor, wherein a gate electrode of the second detection transistor is electrically connected with a second detection control line, a first electrode of the second detection transistor is electrically connected with a second test signal transmission line, and a second electrode of the second detection transistor is electrically connected with the second detection line.

19. A display apparatus, comprising the display panel of claim 1.

20. A crack detection method, applied to the display panel of claim 1, wherein the crack detection method comprises:
providing the first test signal to the first detection line through the first detection control unit; and
determining whether there is a crack in the peripheral region and a position where the crack is located according to a light emitting state of the plurality of sub-pixels electrically connected to the first detection line.

21-25. (canceled)
